(19) United States
(12) Patent Application Publication
(10) Pub. No.: US 2014/0151753 A1
(43) Pub. Date: Jun. 5, 2014

(54) SOLID-STATE IMAGING APPARATUS, MANUFACTURING METHOD THEREOF, AND ELECTRONIC INFORMATION DEVICE

(71) Applicant: Takefumi Konishi, Osaka (JP)

(72) Inventor: Takefumi Konishi, Osaka (JP)

(73) Assignee: SHARP KABUSHIKI KAISHA, Osaka (JP)

(21) Appl. No.: 14/234,798

(22) PCT Filed: May 24, 2012
(86) PCT No.: PCT/JP2012/003402

§ 371 Date: Jan. 24, 2014

(30) Foreign Application Priority Data
Jul. 26, 2011 (JP) 2011-163613

(51) Int. Cl. H01L 27/148; H01L 27/146

(52) U.S. Cl. CPC H01L 27/14806; H01L 27/14689
USPC 257/222; 438/76

(57) ABSTRACT

The solid-state imaging apparatus 100a comprises: photoelectric conversion elements PD1 and PD2 formed within a semiconductor substrate 100; and transfer transistors Tt1 and Tt2 formed on a first main surface of the semiconductor substrate 100, for transferring the signal charge generated by the photoelectric conversion elements PD1 and PD2. The gate electrode 107 of each of the transfer transistors is configured to be disposed over a surface of a first main surface side of an electric charge accumulating region 102, which configures each of the photoelectric conversion elements. The gate electrode 107 is configured with a polysilicon gate layer 107a and a reflection film consisting of a high melting point metal silicide layer 107b for covering the surface of the polysilicon gate layer 107a. As a result, the improvement of sensitivity is achieved for the solid-state imaging apparatus.

### TECHNICAL FIELD

The present invention relates to a solid-state imaging apparatus and a manufacturing method of the solid-state imaging apparatus, and an electronic information device. More particularly, the present invention relates to: a solid-state imaging apparatus for photoelectrically converting incident light from a subject, which has entered from one surface of a semiconductor substrate, by a photoelectric conversion element within the semiconductor substrate, and converting signal charges obtained by the photoelectric conversion into electric signals on the other surface side of the semiconductor substrate to capture an image, and a manufacturing method of the solid-state imaging apparatus; and an electronic information device equipped with such a solid-state imaging apparatus.

### BACKGROUND ART

In recent years, the development of a solid-state imaging apparatus, in which incident light enters the back surface side of a substrate, has been advanced as a highly sensitive solid-state imaging apparatus. Such a type of solid-state imaging apparatus includes circuit elements, wiring layers and the like formed on the front surface side of a silicon substrate, and is configured to allow light to enter the back surface side of the silicon substrate to capture an image.

For example, Patent Literature 1 discloses such a conventional, solid-state imaging apparatus (CMOS image sensor).

FIG. 13 is a diagram for describing a solid-state imaging apparatus disclosed in Patent Literature 1.

In this solid-state imaging apparatus 1, a pixel separating region 12 for separating pixels is formed in a semiconductor substrate 11. A silicon substrate, for example, is used for the semiconductor substrate 11. The pixel separating region 12 is formed with a p-type well region, for example. A photoelectric conversion section 21 is formed in a region divided by the pixel separating region 12. A hole accumulating layer 22 is formed on the side through which light enters of the photoelectric conversion section 21 (the lower part side of the photoelectric conversion section 21 in the figure). The hole accumulating layer 22 is formed with a p⁺ region, for example. Further, a hole accumulating layer 23 is formed on the opposite side from the side through which light enters of the photoelectric conversion section 21 (upper side of the photoelectric conversion section 21 in the figure), and an n-type well region (n-type electric charge accumulating region) 24 is formed in a layer therebelow. The hole accumulating layer 23 is formed with a p⁺ region, for example. Further, a gate electrode (e.g., transfer gate) 32 is formed above the photoelectric conversion section 21 with a gate insulation film 31 interposed therebetween. Further, an n⁺ region 25 is formed on the one end and side of the gate electrode 32 in the semiconductor substrate 11.

A contact section 41 is connected on the gate electrode 32, and a contact section 42 is connected on the pixel separating region 12. Further, a reflection layer 43 is formed above the photoelectric conversion section 21 with the gate insulation film 31 interposed therebetween, where the reflection layer 43 consists of a contact section similar to the contact section 41 or 42. Further, another contact section is also formed that is connected with other transistors (e.g., gate electrode, source and drain regions, and the like) of a signal circuit section (not shown). An insulation film 81 is formed on the gate insulation film 31 and the gate electrode 32, and the respective contact sections are formed by embedding an electric conductor, for example, in a hole 91, 92, 93 or the like that is formed in the insulation film 81.

The reflection layer 43 needs to be a layer that reflects light that has been transmitted through the photoelectric conversion section 21 back towards the photoelectric conversion section 21. For example, the reflection layer 43 consists of matters that reflect at least light in a long-wave length region, such as near infrared ray and infrared ray, back towards the photoelectric conversion section 21. The reflection layer 43 may also be a layer that reflects, not only the light in a long-wave length region as described above, but also light with a wavelength shorter than the wavelength of the long-wave length region, such as visible light, near ultraviolet ray and ultraviolet ray. An example of the material that has such a characteristic is a tungsten layer.

Further, first wires 51 to 53 are formed that are connected with the contact section 41 or 42 or the reflection layer 43.

Second wires 61 to 63 are connected with the first wires 51 to 53, with vias 54 to 56 interposed therebetween. Similarly, third wires 71 to 73 are connected with the second wires 61 to 63, with vias 64 to 66 interposed therebetween.

Further, an insulation film 80 including the insulation film 81 is formed in such a manner to cover the wiring layers described above. The insulation film 80 is formed with a plurality of layers of insulation films in accordance with the formation of wiring. Further, although not shown, a signal circuit section consisting of a group of transistors, such as a selection transistor, a reset transistor and an amplifying transistor, and wiring layers, such as the first wires 51 to 53, the vias 54 to 56, the second wires 61 to 63, the vias 64 to 66, and the third wires 71 to 73, is formed on the opposite side from the side through which light enters of the semiconductor substrate 11.

### CITATION LIST

### Patent Literature

### [PTL 1]

### Japanese Patent No. 4525671

### SUMMARY OF INVENTION

### Technical Problem

In the solid-state imaging apparatus 1 disclosed in Patent Literature 1 as described above, the transfer gate electrode 32 and the reflection layer 43 are provided above the other surface which is opposite from the one surface of the semiconductor substrate 11 through which light enters, so that it prevents light which has entered one of said surfaces from being transmitted through the semiconductor substrate 11 and escaping to the wiring layer region on the other surface of the semiconductor substrate 11, and incident light can be efficiently photoelectrically converted, thereby improving the sensitivity of the solid-state imaging apparatus 1.

With the conventional technique, however, a gap exists in between the transfer gate electrode 32 and the reflection layer 43, which allows light to escape through the gap and which is a cause of lowering the efficiency of the solid-state imaging apparatus.

The present invention is intended to solve the conventional problems described above. It is an objective of the present invention to provide: a solid-state imaging apparatus capable of achieving improved sensitivity by efficiently reflecting light that has entered through the other of the surfaces of a semiconductor substrate, which is opposite from one of surfaces, within which a photoelectric conversion element is formed, by a reflection film formed above one of the surfaces of the semiconductor substrate; a method for manufacturing the solid-state imaging apparatus; and an electronic information device.

### Solution to Problem

A solid-state imaging apparatus according to the present invention comprises a photoelectric conversion element formed in a first conductivity type semiconductor substrate, for photoelectrically converting incident light to generate signal charges, in which the signal charges generated by the photoelectric conversion element are converted into an image signal by signal processing which is outputted, the solid-state imaging apparatus further comprising a transfer transistor formed on a first main surface of the semiconductor substrate, for transferring the signal charges generated by the photoelectric conversion element to outside the photoelectric conversion element, where the transfer transistor comprises a gate electrode located in such a manner to extend from a region occupied by the transfer transistor on the first main surface to a region occupied by the photoelectric conversion element on the first main surface, and is disposed over the regions, and where at least a part of at least one layer constituting the gate electrode of the transfer transistor is comprised of a reflection film, or a reflection film is formed in an at least a part of a region on the gate electrode of the transfer transistor, thereby achieving the objective described above.

Preferably, in a solid-state imaging apparatus according to the present invention, the photoelectric conversion element comprises: a second conductivity type photoelectric conversion region for photoelectrically converting incident light taken from a second main surface of the semiconductor substrate on an opposite side from the first main surface; and a second conductivity type electric charge accumulating region for accumulating, on the first main surface side, the signal charges generated by photoelectric conversion in the second conductivity type photoelectric conversion region, and the gate electrode of the transfer transistor is formed to be disposed over the surface of the first main surface side of the second conductivity type electric charge accumulating region.

Still preferably, in a solid-state imaging apparatus according to the present invention, the solid-state imaging apparatus further comprises: a second conductivity type signal charge accumulating section for accumulating the signal charges transferred from the photoelectric conversion element; and a first conductivity type electric charge transferring region for transferring the signal charges from the second conductivity type electric charge accumulating region to the second conductivity type signal charge accumulating section, where the second conductivity type electric charge accumulating region and the second conductivity type signal charge accumulating section are disposed away from each other with the first conductivity type electric charge transferring region interposed therebetween.

Still preferably, in a solid-state imaging apparatus according to the present invention, a space between the second conductivity type electric charge accumulating region and the second conductivity type signal charge accumulating section is equal to or greater than a minimum distance that does not substantially cause a short channel effect, and is equal to or smaller than a maximum distance that is permissible by a degree of integration of pixels in the solid-state imaging apparatus.

Still preferably, in a solid-state imaging apparatus according to the present invention, a space between the second conductivity type electric charge accumulating region and the second conductivity type signal charge accumulating section is within the range of
0.2 μm to 1.0 μm.

Still preferably, in a solid-state imaging apparatus according to the present invention, the solid-state imaging apparatus further comprises: a first conductivity type well region formed within the first conductivity type semiconductor substrate; and a first conductivity type front surface semiconductor region formed on the first main surface side of the second conductivity type electric charge accumulating region, in such a manner to be disposed over the second conductivity type electric charge accumulating region, and the first conductivity type front surface semiconductor region has impurity concentration that exceeds impurity concentration of the first conductivity type electric charge transferring region and that is equal to or smaller than impurity concentration of the first conductivity type well region.

Still preferably, in a solid-state imaging apparatus according to the present invention, the first conductivity type well region is formed to surround the second conductivity type electric charge accumulating region, the first conductivity type electric charge transferring region and the second conductivity type signal charge accumulating section.

Still preferably, in a solid-state imaging apparatus according to the present invention, the gate electrode of the transfer transistor is formed to be disposed over a region occupied by the first conductivity type well region on the first main surface.

Still preferably, in a solid-state imaging apparatus according to the present invention, the gate electrode of the transfer transistor has a multi-layered structure comprising a polysilicon layer and a high melting point metal silicide layer formed as a reflection film on a surface of the polysilicon layer.

Still preferably, in a solid-state imaging apparatus according to the present invention, a high melting point metal material constituting the high melting point metal silicide layer of the gate electrode of the transfer transistor is tungsten, cobalt, titanium, molybdenum, hafnium, platinum or nickel.

Still preferably, in a solid-state imaging apparatus according to the present invention, the gate electrode of the transfer transistor has a multi-layered structure comprising a polysilicon layer and a metal layer formed as a reflection film on a surface of the polysilicon layer.

Still preferably, in a solid-state imaging apparatus according to the present invention, a metal material constituting the metal layer of the gate electrode of the transfer transistor is tungsten, cobalt, titanium, molybdenum, hafnium, platinum or nickel.

Still preferably, in a solid-state imaging apparatus according to the present invention, the gate electrode of the transfer transistor has a multi-layered structure comprising a polysilicon layer, a high melting point metal silicide layer formed on a surface of the polysilicon layer, and a metal layer formed on a surface of the high melting point metal silicide layer, the high melting point metal silicide layer and the metal layer being formed as a reflection film.

Still preferably, in a solid-state imaging apparatus according to the present invention, a high melting point metal material constituting the high melting point metal silicide layer of the gate electrode of the transfer transistor is tungsten, cobalt, titanium, molybdenum, hafnium, platinum or nickel, and a metal material constituting the metal layer of the gate electrode of the transfer transistor is tungsten, cobalt, titanium, molybdenum, hafnium, platinum or nickel.

Still preferably, in a solid-state imaging apparatus according to the present invention, the gate electrode of the transfer transistor has a single-layered structure consisting of a high melting point metal layer.

A method for manufacturing a solid-state imaging apparatus according to the present invention comprises: a step of forming the photoelectric conversion element within the first conductivity type semiconductor substrate; and a step of forming the transfer transistor on the first main surface side in the first conductivity type semiconductor substrate, where the step of forming the transfer transistor comprises: a step of depositing a constituent material of the gate electrode of the transfer transistor on the first main surface; and a step of forming a gate electrode by selectively etching the deposited constituent material of the gate electrode, so that the gate electrode extends from the region occupied by the transfer transistor on the first main surface to the region occupied by the photoelectric conversion element on the first main surface, and is disposed over the regions, and where the step of forming a gate electrode comprises a step of forming the reflection film as at least a part of at least one layer constituting the gate electrode, or the method for manufacturing a solid-state imaging apparatus comprises a step of forming the reflection film in at least a part of a region on the gate electrode of the transfer transistor, thereby achieving the objective described above.

A method for manufacturing a solid-state imaging apparatus according to the present invention comprises: a step of forming the photoelectric conversion element within the first conductivity type semiconductor substrate; and a step of forming the transfer transistor in the first conductivity type semiconductor substrate on the first main surface side, where the step of forming the transfer transistor comprises: a step of depositing a constituent material of the gate electrode of the transfer transistor on the first main surface; a step of forming a gate electrode by selectively etching the deposited constituent material of the gate electrode, so that the gate electrode extends through the region occupied by the transfer transistor on the first main surface to the region occupied by the photoelectric conversion element on the first main surface, and is disposed over the regions; and a step of forming the second conductivity type signal charge accumulating section by performing ion implantation using the gate electrode of the transfer transistor as a mask, thereby achieving the objective described above.

A method for manufacturing a solid-state imaging apparatus according to the present invention comprises: a step of forming the photoelectric conversion element within the first conductivity type semiconductor substrate; and a step of forming the transfer transistor on the first main surface side in the first conductivity type semiconductor substrate, where the step of forming the photoelectric conversion element comprises: a step of forming the second conductivity type electric charge accumulating region within the first conductivity type semiconductor substrate; and a step of forming the first conductivity type front surface semiconductor region on the first main surface side in the second conductivity type electric charge accumulating region so as to cover the second conductivity type electric charge accumulating region, and where the second conductivity type electric charge accumulating region and the first conductivity type semiconductor substrate are formed by impurity implantation using the same ion implantation mask, thereby achieving the objective described above.

A method for manufacturing a solid-state imaging apparatus according to the present invention comprises: a step of forming the photoelectric conversion element within the first conductivity type semiconductor substrate; and a step of forming the transfer transistor in the first conductivity type semiconductor substrate on the first main surface side, where the step of forming the transfer transistor comprises: a step of depositing the polysilicon layer on the first main surface; a step of forming a polysilicon gate layer by selectively etching the deposited polysilicon layer, so that the polysilicon gate layer extends from a region occupied by the transfer transistor on the first main surface to a region occupied by the photoelectric conversion element on the first main surface, and is disposed over the regions; and a step of forming a high melting point metal silicide layer on a surface of the polysilicon gate layer, thereby achieving the objective described above.

A method for manufacturing a solid-state imaging apparatus according to the present invention comprises: a step of forming the photoelectric conversion element within the first conductivity type semiconductor substrate; and a step of forming the transfer transistor in the first conductivity type semiconductor substrate on the first main surface side, where the step of forming the transfer transistor comprises: a step of depositing the polysilicon layer on the first main surface; a step of forming a polysilicon gate layer by selectively etching the deposited polysilicon layer, so that the polysilicon gate layer extends from a region occupied by the transfer transistor on the first main surface to a region occupied by the photoelectric conversion element on the first main surface, and is disposed over the regions; and a step of forming a metal layer on a surface of the polysilicon gate layer, thereby achieving the objective described above.

A method for manufacturing a solid-state imaging apparatus according to the present invention comprises: a step of forming the photoelectric conversion element within the first conductivity type semiconductor substrate; and a step of forming the transfer transistor in the first conductivity type semiconductor substrate on the first main surface side, where the step of forming the transfer transistor comprises: a step of depositing the polysilicon layer, the high melting point metal silicide layer and the metal layer successively on the first main surface; and a step of forming a gate electrode having a multi-layered structure comprising the polysilicon layer, the high melting point metal silicide layer and the metal layer by selectively etching the deposited polysilicon layer, high melting point metal silicide layer and metal layer, so that the gate electrode extends through a region occupied by the transfer transistor on the first main surface to a region occupied by the photoelectric conversion element on the first main surface, and is disposed over the regions, thereby achieving the objective described above.

A method for manufacturing a solid-state imaging apparatus according to the present invention comprises: a step of forming the photoelectric conversion element within the first conductivity type semiconductor substrate; and a step of forming the transfer transistor in the first conductivity type semiconductor substrate on the first main surface side, where the step of forming the transfer transistor comprises: a step of forming the high melting point metal layer on the first main surface; and a step of forming a gate electrode consisting of the high melting point metal layer by selectively etching the formed high melting point metal layer so that the gate electrode extends from a region occupied by the transfer transistor on the first main surface to a region occupied by the photoelectric conversion element on the first main surface, and is disposed over the regions, thereby achieving the objective described above.

An electronic information device according to the present invention comprises the solid-state imaging apparatus according to the present invention.

Next, the functions of the solid-state imaging apparatus according to the present invention will be described.

In the present invention, the gate electrode of the transfer transistor is formed such that the gate electrode extends from a region occupied by the transfer transistor on the first main surface in the semiconductor substrate to a region occupied by the photoelectric conversion element on the first main surface, and is disposed over the regions, and at least a part of at least one layer constituting the gate electrode of the transfer transistor is constituted by a reflection film, or alternatively, a reflection film is formed in at least a part of a region on the gate electrode of the transfer transistor. Thus, light, which has entered through a second main surface of the semiconductor substrate that is opposite from the first main surface of the semiconductor substrate and which has been transmitted through the semiconductor substrate, is reflected by the reflection film of this transfer gate electrode and is returned back into the semiconductor substrate. This prevents the light from escaping between the region occupied by the transfer transistor on the first main surface and the region occupied by the photoelectric conversion element on the first main surface, of the semiconductor substrate, and this allows for the efficient use of incident light.

Further, in the present invention, the gate electrode of the transfer transistor is formed to be disposed over the first main surface of the second conductivity type electric charge accumulating region of the photoelectric conversion element. Thus, the second conductivity type electric charge accumulating region of the photoelectric conversion element will not receive any damage due to plasma etching from the process of forming the gate electrode of the transfer transistor, and the generation of noise electric charges due to crystal defects can be suppressed. As a result, the impurity concentration can be reduced in the first conductivity type semiconductor region that is formed in the front surface region of the second conductivity type electric charge accumulating region, and the impurity concentration can be suppressed low in the first conductivity type electric charge transferring region adjacent to this second conductivity type electric charge accumulating region. As a result, the amount of the variation in the potential level in this first conductivity type electric charge transferring region can be greater, thereby increasing the efficiency of transferring electric charges.

Further, since all of the impurity regions within the semiconductor substrate, other than the signal charge accumulating section, are formed prior to the formation of the gate electrode of the transfer transistor, the impurity regions within the semiconductor substrate, other than the signal charge accumulating section, are formed in the state where the impurity regions have not been damaged by plasma etching at the forming of the transfer gate electrode. This will enable securing favorable crystallinity, and eliminate causes of deteriorating the characteristics, such as leak current.

### Advantageous Effects of Invention

According to the present invention as described above, it is possible to obtain a solid-state imaging apparatus capable of achieving improved sensitivity by efficiently reflecting light that has entered through the other of the surfaces of a semiconductor substrate, which is opposite from one of the surfaces of the semiconductor substrate, within which a photoelectric conversion element is formed, by a reflection film formed above one of the surfaces of the semiconductor substrate; a method for manufacturing the solid-state imaging apparatus; and an electronic information device equipped with the solid-state imaging apparatus.

### BRIEF DESCRIPTION OF DRAWINGS

FIG. 1 is a diagram for describing a solid-state imaging apparatus according to Embodiment 1 of the present application, where FIG. 1(a) schematically illustrates an overall configuration of the solid-state imaging apparatus and FIG. 1(b) illustrates circuits that constitute a pixel in the solid-state imaging apparatus.

FIG. 2 is a planer view for describing a solid-state imaging apparatus according to Embodiment 1 of the present invention, where FIG. 2(a) illustrates a disposition of an impurity implantation region with respect to an element separating region, and where FIG. 2(b) illustrates a disposition of a gate electrode of a transfer transistor and a contact section with respect to an element separating region.

FIG. 3 is a diagram for describing a solid-state imaging apparatus according to Embodiment 1 of the present invention, illustrating a cross sectional view along the line A-A′ in FIG. 2(b).

FIG. 4 is a diagram illustrating an operation of a solid-state imaging apparatus according to Embodiment 1 of the present invention, where FIG. 4(a) illustrates a potential distribution during an electric charge accumulating period in a path from a surface through which light enters of a semiconductor substrate through a photoelectric conversion element to a signal charge accumulating section, and where FIG. 4(b) illustrates a potential distribution of the electric charge accumulating period in this path.

FIG. 5 is a diagram for describing a method for manufacturing a solid-state imaging apparatus according to Embodiment 1 of the present invention, where FIGS. 5(a) to 5(e) each illustrate a cross sectional view for describing a step of forming a photoelectric conversion element and a step of forming a polysilicon layer constituting a transfer gate electrode.

FIG. 6 is a diagram for describing a method for manufacturing a solid-state imaging apparatus according to Embodiment 1 of the present invention, where FIGS. 6(a) to 6(e) each illustrate a cross sectional view for describing a step of forming a reflection film constituting a transfer gate electrode.

FIG. 7 is a diagram for describing a solid-state imaging apparatus according to Embodiment 2 of the present invention, where it illustrates a portion corresponding to a cross sectional view along the line A-A′ in FIG. 2(b).

FIG. 8 is a diagram for describing a solid-state imaging apparatus according to Embodiment 3 of the present invention, where it illustrates a portion corresponding to a cross sectional view along the line A-A′ in FIG. 2(b).

FIG. 9 is a diagram for describing a solid-state imaging apparatus according to Embodiment 4 of the present invention, illustrating a portion corresponding to a cross sectional view along the line A-A′ in FIG. 2(b).

FIG. 10 is a plane view for describing a solid-state imaging apparatus according to Embodiment 5 of the present invention, where FIG. 10(a) illustrates a disposition of an impurity implantation region relative to an element separating region and where FIG. 10(b) illustrates a disposition of a transfer gate electrode and a contact section relative to an element separating region.

FIG. 11 is a diagram for describing a solid-state imaging apparatus according to Embodiment 5 of the present invention, illustrating a cross sectional view along the line A-A′ in FIG. 10(b).

FIG. 12 is a block diagram schematically illustrating an exemplary configuration of an electronic information device, as Embodiment 6 of the present invention, using the solid-state imaging apparatus according to any of Embodiments 1 to 5 in an imaging section.

FIG. 13 is a diagram for describing a solid-state imaging apparatus disclosed in Patent Literature 1.

### DESCRIPTION OF EMBODIMENTS

Hereinafter, embodiments of the present invention will be described with reference to accompanying figures.

### Embodiment 1

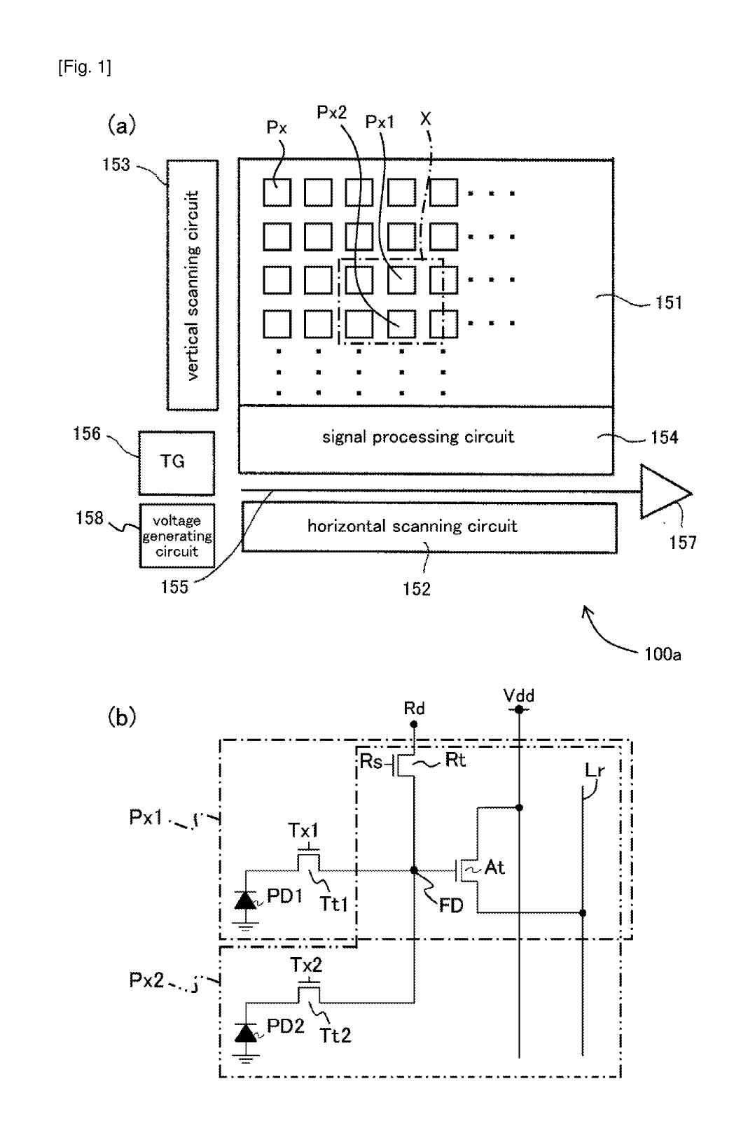

FIG. 1 is a diagram for describing a solid-state imaging apparatus according to Embodiment 1 of the present application, where FIG. 1(a) schematically illustrates an overall configuration of the solid-state imaging apparatus and FIG. 1(b) illustrates circuits that constitute a pixel in the solid-state imaging apparatus.

A solid-state imaging apparatus 100a according to Embodiment 1 comprises: a pixel section 151 comprising a plurality of pixels arranged in rows and columns; a vertical scanning circuit 153 for selecting a pixel row, which is a pixel arrangement in the horizontal direction in the pixel section 151; and a signal processing circuit 154 comprising an AD conversion section for converting analog pixel signals from each of the pixels in a selected pixel row into digital pixel signals by signal processing and retaining the digital pixel signals. The solid-state imaging apparatus 100a comprises: a horizontal scanning circuit 152 for outputting a scanning signal to a signal processing circuit 154 so that the signal processing circuit 154 will successively output a digital pixel signal of each pixel to a horizontal signal line 155; and an output section 157 for outputting the digital pixel signal outputted to the horizontal signal line 155 to the outside of the solid-state imaging apparatus 100a. The solid-state imaging apparatus 100a further comprises: a timing generating section 156 for supplying a timing signal to the vertical scanning circuit 153, the horizontal scanning circuit 152 and the signal processing circuit 154; and a voltage generating circuit 158 for generating negative voltage.

Here, the pixel section 151 is configured on a first conductivity type semiconductor substrate (hereinafter, simply referred to as a semiconductor substrate). The vertical scanning circuit 153, horizontal scanning circuit 152, signal processing circuit 154, timing generating section 156 and voltage generating circuit 158 are disposed in the peripheral region of the pixel section 151 of the semiconductor substrate. These circuits and sections constitute a peripheral circuit section for converting an analog pixel signal into a digital pixel signal and outputting the digital pixel signal as an image signal, where the analog pixel signal is signal charges generated by photoelectric conversion of incident light at a photoelectric conversion element that constitutes each pixel of the pixel section. Note that the voltage generating circuit 158 generates negative voltage here. However, the voltage generated by the voltage generating circuit 158 is not limited to negative voltage.

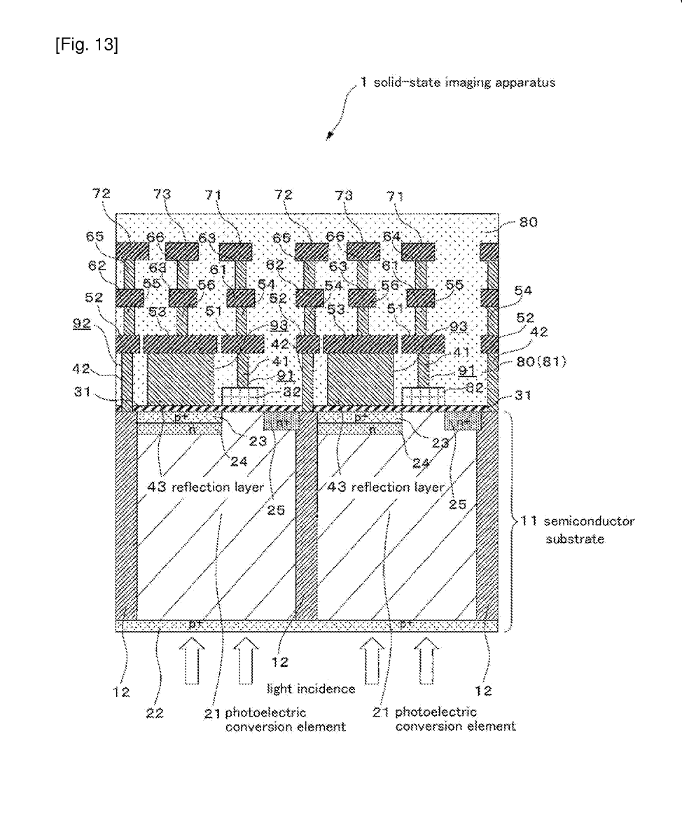

While the overall configuration of the solid-state imaging apparatus 100a illustrated in FIG. 1 is similar to that of a typical CMOS solid-state imaging apparatus, the solid-state imaging apparatus 100a according to Embodiment 1 is different from the conventional solid-state imaging apparatus 1 illustrated in FIG. 13, in that the planar shape of the transfer gate electrode 32 is changed and the front surface of the transfer gate electrode 32 is covered with a film consisting of a material having higher light reflectivity than the transfer gate electrode 32.

While the pixel in the solid-state imaging apparatus 100a according to Embodiment 1 of the present invention has a three transistor configuration comprising a transfer transistor, a reset transistor and an amplifying transistor, it is needless to say that instead of the three transistor configuration, the pixel of the solid-state imaging apparatus 100a may have a four transistor configuration comprising a selection transistor for selecting a pixel row, in addition to said transistors.

Further, as illustrated in FIG. 1(a), while a plurality of pixels Px are arranged in rows and columns in the pixel section 151, the pixels in the pixel section 151 in the fourth column from the left and in the third and fourth rows from the top of the figure will be particularly referred to as pixels Px1 and Px2, for the convenience of explanation herein, and the specific pixel configuration will be described hereinafter.

First, the circuit configuration of the pixel illustrated in FIG. 1(b) will be described.

The pixel Px1 comprises: a photoelectric conversion element PD1 for generating signal charges by photoelectric conversion of incident light; a transfer transistor Tt1 for transferring the signal charges generated by the photoelectric conversion element PD1 to a signal charge accumulating section FD outside the photoelectric conversion element on the basis of a transfer signal Tx1; a reset transistor Rt for resetting signal charges in the signal charge accumulating section FD on the basis of a reset signal Rs; and an amplifying transistor At for amplifying signal voltage generated in accordance with signal charges accumulated in the signal charge accumulating section FD, and outputting the signal voltage to a reading signal line Lr.

The pixel Px2 comprises: a photoelectric conversion element PD2 for generating signal charges by photoelectric conversion of incident light; a transfer transistor Tt2 for transferring signal charges generated by the photoelectric conversion element PD2 to the signal charge accumulating section FD outside the photoelectric conversion element on the basis of a transfer signal Tx2; a reset transistor Rt for resetting signal charges in a signal charge accumulating section FD on the basis of a reset signal R; and an amplifying transistor At for amplifying signal voltage generated in accordance with signal charges accumulated in the signal charge accumulating section FD, and outputting the signal voltage to a reading signal line Lr.

Specifically, in the pixel section 151, the circuit for configuring the pixel Px has a two-pixel sharing configuration, in which two pixels positioned adjacent to each other top and bottom (e.g., pixel Px1 and pixel Px2 illustrated in FIGS. 1(a) and 1(b)) share the reset transistor Rt and the amplifying transistor At.

Here, the reset transistor Rt is connected in between a drain signal line Rd and a signal charge accumulating section FD, and the signal charge accumulating section ID is connected with a gate electrode of the amplifying transistor At. Further, the transfer transistor Tt1 and the photoelectric conversion element PD1 are connected in series in between the signal charge accumulating section FD and the grounding node. Similarly, the transfer transistor Tt2 and the photoelectric conversion element PD2 are connected in series in between the signal charge accumulating section FD and the grounding node. The photoelectric conversion elements PD1 and PD2 are each configured with a photodiode.

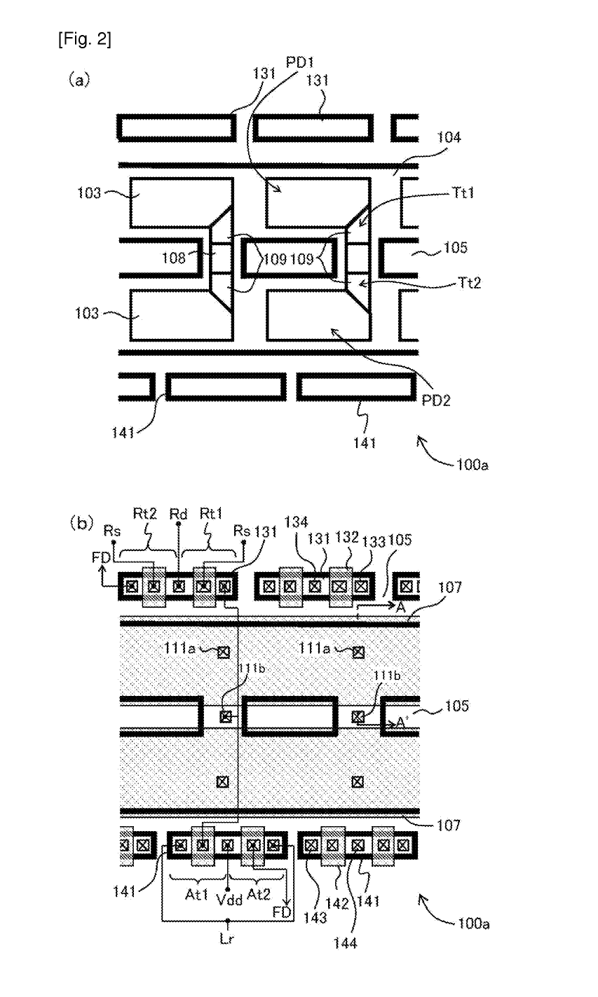

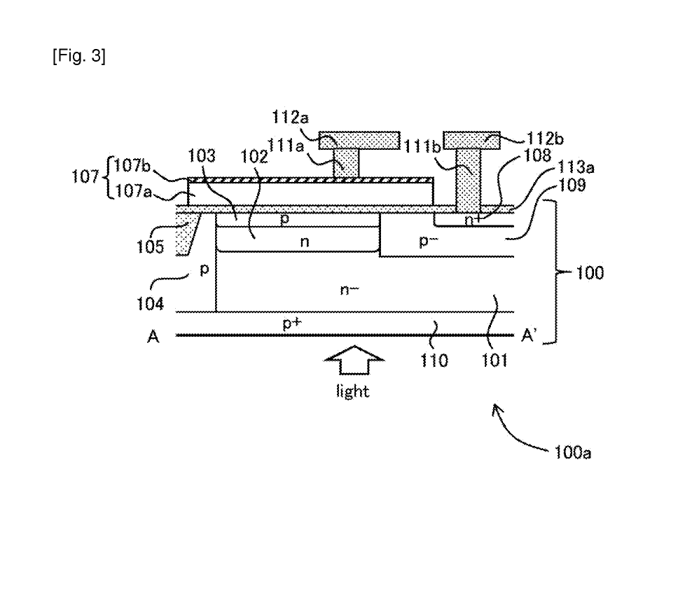

Next, a detailed structure of the pixel section in the solid-state imaging apparatus according to Embodiment 1 will be described with reference to FIGS. 2 and 3.

FIG. 2 is a planer view for describing the solid-state imaging apparatus according to Embodiment 1 of the present invention, where FIG. 2(a) illustrates a disposition of an impurity implantation region with respect to an element separating region, and where FIG. 2(b) illustrates a disposition of a gate electrode of a transfer transistor and a contact section with respect to the element separating region.

Further, FIG. 3 is a cross sectional view along the line A-A′ in FIG. 2(b). The planer view of FIG. 2(b) illustrates the disposition of various impurity implantation regions that appear on the semiconductor substrate, with regard to the part X surrounded by the alternate long and short dash line of the pixel section 151 illustrated in FIG. 1(a).

In the solid-state imaging apparatus 100a according to Embodiment 1 of the present invention, respective pixels Px, such as pixels Px1 and Px2, that configure the pixel section 151 formed on a first conductivity type semiconductor substrate 100, such as a p-type silicon substrate, comprise photoelectric conversion elements (i.e., photodiodes) PD1 and PD2 formed within the semiconductor substrate 100 for generating signal charges by photoelectric conversion of incident light, and transfer transistors Tt1 and Tt2 formed on a first main surface of the semiconductor substrate 100, for transferring the signal charges generated by the photoelectric conversion elements PD1 and PD2. The first main surface described above is the upper surface of the semiconductor substrate 100 (hereinafter, also referred to as a front substrate surface) in FIG. 3, and FIG. 3 illustrates the structure of the transfer transistor Tt1 of the pixel Px1 as well as the photoelectric conversion element PD1 and a signal charge accumulating section 108 (FD in FIG. 1(b)) that are positioned on either side of the transfer transistor Tt1. Note that while FIG. 3 illustrates a cross sectional structure of the pixel Px1, other pixels Px are identical to this pixel Px1.

Here, the photoelectric conversion element PD1 of the pixel Px1 comprises: a second conductivity type photoelectric conversion region (n⁻ type semiconductor region) 101 for photoelectrically converting incident light, which has entered through a second main surface of the semiconductor substrate that is opposite from the first main surface; and a second conductivity type electric charge accumulating region (n type semiconductor region) 102 for accumulating the signal charges generated by photoelectric conversion at the photoelectric conversion region 101, on the first main surface side of the semiconductor substrate 100. A gate electrode 107 (hereinafter, also referred to as a transfer gate electrode) of the transfer transistor is formed to be disposed over the surface on the first main surface side of the electric charge accumulating region 102. Here, the second main surface is a lower surface of the semiconductor substrate 100 in FIG. 3, which is also referred to as a back substrate surface hereinafter.

The transfer gate electrode 107 is comprised of: a polysilicon layer 107a formed above the semiconductor substrate 100 with a gate insulation film 113a interposed therebetween; and a high melting point metal silicide layer 107b formed to cover the surface of the polysilicon layer 107a. Here, the high melting point metal that is the constituent material of the high melting point metal silicide layer 107b is tungsten, cobalt, titanium, molybdenum, hafnium, platinum or nickel, which is a material that has higher light reflectivity than polysilicon. Further, the high melting point metal silicide layer 107b has a function of reflecting light back towards the inside of the substrate, the light having entered into a back substrate surface, having been transmitted through the semiconductor region that constitutes a photoelectric conversion element, and further having been transmitted through the polysilicon layer 107a.

Further, in the solid-state imaging apparatus 100a, the photoelectric conversion element PD1 comprises a first conductivity type front surface semiconductor region (front surface p region) 103 formed on the front substrate side of the second conductivity type electric charge accumulating region 102, so as to be disposed over the electric charge accumulating region 102. Further, the pixel Pzl comprises: a second conductivity type signal charge accumulating section (electric charge accumulating n⁺ region) 108, formed away from the second conductivity type electric charge accumulating region 102 with a space of
0.2 μm to 1.0 μm
therebetween, for accumulating signal charges generated by the photoelectric conversion element PD1; and a first conductivity type electric charge transferring region (electric charge transfer section p⁻ region) 109 disposed in between the signal charge accumulating section 108 outside the photoelectric conversion element and the electric charge accumulating region 102 of the photoelectric conversion element, for transferring the signal charges from the electric charge accumulating region 102 of the photoelectric conversion element PD1 to the signal charge accumulating section 108 outside the photoelectric conversion element. The first conductivity type electric charge transferring region (electric charge transfer section p⁻ region) 109 comprises a channel region of the transfer transistor Tt1. The front surface p region 103 has an impurity concentration that exceeds the impurity concentration of the first conductivity type electric charge transferring region 109.

Here, the second conductivity type electric charge accumulating region (n type semiconductor region) 102 and the second conductivity type signal charge accumulating section (electric charge accumulating n⁺ region) 108 are disposed away from each other, with the first conductivity type electric charge transferring region (electric charge transfer section p⁻ region) 109 interposed therebetween. The lower limit of the space between the electric charge accumulating region 102 and the signal charge accumulating section 108 may be equal to or greater than a minimum distance that does not substantially cause a short channel effect. Further, the upper limit of the space between the electric charge accumulating region 102 and the signal charge accumulating section 108 may be equal to or smaller than a permissible maximum distance that is determined by the degree of integration of pixels in the solid-state imaging apparatus. Specifically, as long as the space between the electric charge accumulating region 102 and the signal charge accumulating section 108 is equal to or greater than a minimum distance that does not substantially cause a short channel effect, and is equal to or smaller than a permissible maximum distance that is determined by the degree of integration of pixels in the solid-state imaging apparatus, it is within the range of the present invention. The space between the electric charge accumulating region 102 and the signal charge accumulating section 108 is within the range of
0.2 μm to 1.0 μm,
for example. This is because, in the existing circumstances, the minimum distance that does not cause a short channel effect is
0.2 μm
and the permissible maximum distance that is determined by the degree of integration of pixels in the solid-state imaging apparatus is
1.0 μm.

However, owing to the progress in fine processing techniques, the lower limit of the space described above has a tendency to be smaller than the current lower limit. Thus, in the future, the lower limit of the space described above may be smaller than the current value,
0.2 μm (e.g., 0.1 μm).

Either way, as long as the space between the electric charge accumulating region 102 and the signal charge accumulating section 108 is equal to or greater than a minimum distance that does not substantially cause a short channel effect, and is equal to or smaller than a permissible maximum distance that is determined by the degree of integration of pixels in the solid-state imaging apparatus, it is within the range of the present invention, as described above.

Further, the second conductivity type electric charge accumulating region 102, the first conductivity type electric charge transferring region 109 and the second conductivity type signal charge accumulating section 108 are surrounded by a first conductivity type well region (p-well region) 104 formed in the semiconductor substrate 100. The second conductivity type electric charge accumulating region 102, the second conductivity type electric charge transferring region 109 and the second conductivity type signal charge accumulating section 108 are electrically separated from one another by the first conductivity type well region 104 for each two pixels that share the same second conductivity type signal charge accumulating section 108.

Further, the front surface p region 103 has an impurity concentration that is equal to or smaller than the impurity concentration of the first conductivity type well region 104. By setting the impurity concentration of the first conductivity type well region 104 to be 1×10¹⁸ cm⁻³ or smaller, the ion implantation damage to the well region 104 can be reduced and thus the generation of noise electric charges can be suppressed.

Further, the first conductivity type front surface semiconductor region 103 is configured with a p type semiconductor layer of
0.1 μm to 0.3 μm
in thickness, and the first conductivity type electric charge accumulating region 102, which constitutes the photoelectric conversion element, is formed such that the peak position of its impurity concentration is at a position
0.15 μm to 0.40 μm
in depth from the first main surface of the semiconductor substrate.

Further, an element separating region 105 is positioned in between the photoelectric conversion elements PD1 and PD2 that are adjacent to each other top and bottom, and the element separating region 105 is also positioned in between second conductivity type signal charge accumulating sections 108 that are arranged in the horizontal direction in the same pitch as the arrangement pitch of the photoelectric conversion elements. Further, by the element separating region 105, two lines of top and bottom arrangement regions for photoelectric conversion elements, in which photoelectric conversion elements are arranged, are also electrically separated from belt-shaped diffusion regions 131 and 141 for the reset transistor Rt and amplification transistor At.

The element separating region 105 is such a region that is made by filling a trench formed in the semiconductor substrate 100 with an insulating member, such as silicon oxide, into. Further, the back surface p⁺ region 110 is formed on the back surface side of the semiconductor substrate 100.

The connection of transistors in a circuit that constitutes a pixel will be described with reference to FIGS. 2 and 3.

In order to avoid complicity, FIG. 2(a) and FIG. 2(b) illustrate the connection between transistors in photoelectric conversion elements located on the left side of the photoelectric conversion elements PD1 and PD2 in the figure, while the connection between transistors in the photoelectric conversion elements PD1 and PD2 is the same as that in the photoelectric conversion elements located on the left side of the photoelectric conversion elements PD1 and PD2 in the figures.

Two reset transistors Rt1 and Rt2 are formed on the belt-shaped diffusion region 131, and two reset gate electrodes 132 to which a reset signal Rs is applied are disposed in such a manner to intersect with the belt-shaped diffusion region 131, with a gate insulation film (not shown) interposed therebetween. A drain signal Rd for row selection is applied through a contact section 134 to a common drain region between the two reset gate electrodes 132 in the belt-shaped diffusion region 131. Specifically, when the drain signal Rd is at a high level, a pixel row is selected; and when the drain signal Rd is at a low level, a pixel row is not selected. Further, the source region of one of the reset transistors, i.e., reset transistor Rt1, is connected with wiring 112b that is connected with the signal charge accumulating section (FD section) 108, with a contact section 133 interposed therebetween. The source region of the other reset transistor, i.e., reset transistor Rt2, is connected with a signal charge accumulating section (FD section) common to the pixel in the first row and the pixel in the second row in the pixel section 151 illustrated in FIG. 1.

Two amplifying transistors At1 and At2 are formed on the belt-shaped diffusion region 141, and an amplifying gate electrode 142 is disposed in such a manner to intersect with the belt-shaped diffusion region 141, with a gate insulation film (not shown) interposed therebetween. A power source voltage Vdd (e.g., 2.5V) is applied through a contact section 144 to a common drain region between the two amplifying gate electrodes 142 in the belt-shaped diffusion region 141. Further, the source region of one of the amplifying transistors, i.e., amplifying transistor At1, is connected with a reading signal line Lr with a contact section 143 interposed therebetween. The source region of the other amplifying transistor, i.e., amplifying transistor At2, is also connected with the reading signal line Lr corresponding to the same pixel column, with the contact section 143 interposed therebetween. Further, the gate electrode 142 of one of the amplifying transistors, i.e., amplifying transistor At1, is connected with wiring 112b that is connected with the signal charge accumulating section (FD section) 108. The gate electrode 142 of the other amplifying transistor, i.e., amplifying transistor At2, is connected with a signal charge accumulating section (FD section) common to the pixel in the fifth row and the pixel in the sixth row of the pixel section 151 illustrated in FIG. 1.

Further, the transfer gate electrode 107 is connected with a wiring layer 112a with a contact section 111a interposed therebetween. Further, the signal charge accumulating section (FD section) 108 is connected with a wiring layer 112b with a contact section 111b interposed therebetween. Here, the wiring layers 112a and 112b are formed by patterning a wiring material formed above the transfer gate electrode 107 with an interlayer insulation film (not shown) interposed therebetween.

Hereinafter, impurity concentrations of semiconductor substrates and the respective semiconductor regions constituting the solid-state imaging apparatus according to the present invention will be described.

The impurity concentration of the second conductivity type photoelectric conversion region (n⁻ type semiconductor region) 101 constituting a photoelectric conversion element is about 1×10¹⁵ cm⁻³ to about 5×10¹⁶ cm⁻³. The impurity concentration of the second conductivity type electric charge accumulating region (n-type semiconductor region) 102 constituting a photoelectric conversion element is about 1×10¹⁶ cm⁻³ to about 1×10¹⁷ cm⁻³. Further, the impurity concentration of the first conductivity type front surface semiconductor region (front surface p region) 103 formed on the front surface of the n-type semiconductor region 102 is about 1×10¹⁶ cm⁻³ to about 5×10¹⁷ cm⁻³, and the impurity concentration of the first conductivity type well region (p well region) 104 is about 5×10¹⁶ cm⁻³ to about 1×10¹⁸ cm⁻³. Further, the impurity concentration of a second conductivity type signal charge accumulating section (electric charge accumulating n⁺ region), i.e., FD (Floating Diffusion) section 108 is about 1×10¹⁷ cm⁻³ to about 1×10²⁰ cm⁻³, and the impurity concentration of the first conductivity type electric charge transferring region (electric charge transfer section p⁻ region) 109 is about 5×10¹⁵ cm⁻³ to about 1×10¹⁷ cm⁻³, and the impurity concentration of the back surface p⁺ region 110 is about 1×10¹⁸ cm⁻³ to about 1×10¹⁹ cm⁻³.

The photoelectric conversion element described above is specifically an embedded photodiode. In such an embedded photodiode, the first conductivity type front surface semiconductor region (front surface p region) 103 is formed in the front surface of the second conductivity type electric charge accumulating region (n-type electric charge accumulating region) 102, to increase a concentration of holes that couple with noise electric charges (electrons) thermally generated due to crystal defect and the like on the surface of the second conductivity type electric charge accumulating region 102 that accumulates signal charges (electrons), so that noise due to noise electric charges, other than signal charges, is suppressed by the shortening of the life span of noise electric charges.

Next, the operations of the solid-state imaging apparatus according to Embodiment 1 of the present invention will be described hereinafter.

In such a solid-state imaging apparatus 100 according to Embodiment 1 of the present invention that has a configuration as described above, the reading operation is performed in a similar manner as conventional solid-state imaging apparatuses.

Hereinafter, a reading operation in the solid-state imaging apparatus according to Embodiment 1 will be briefly described with reference to FIGS. 1(a) and 1(b).

The vertical scanning circuit 153 selects a pixel row in the pixel section by a timing signal from the timing generating section 156, and a pixel signal of the selected pixel row is outputted to the signal processing circuit 154. In the signal processing circuit 154, a process for removing a fixed noise pattern is performed. Further, as the horizontal scanning circuit 152 outputs a scanning signal, by the timing signal from the timing generating section 156, to the signal processing circuit 154 so that the signal processing circuit 154 will output a digital pixel signal of each pixel successfully to the horizontal signal line 155, the digital signal outputted to the horizontal signal line 155 is outputted outside the solid-state imaging apparatus 100a from the output section 157.

Further, in the solid-state imaging apparatus 100 according to Embodiment 1, during an electric charge accumulating period during which signal charges are generated and accumulated by the photoelectric conversion of incident light at the photoelectric conversion element, 0.1 V to 1.0 V of electrical potential is applied between the transfer gate electrode 107 and the first conductivity type front surface semiconductor region 103 so that the electric potential of the transfer gate electrode 107 will be smaller than that of the first conductivity type front surface semiconductor region 103.

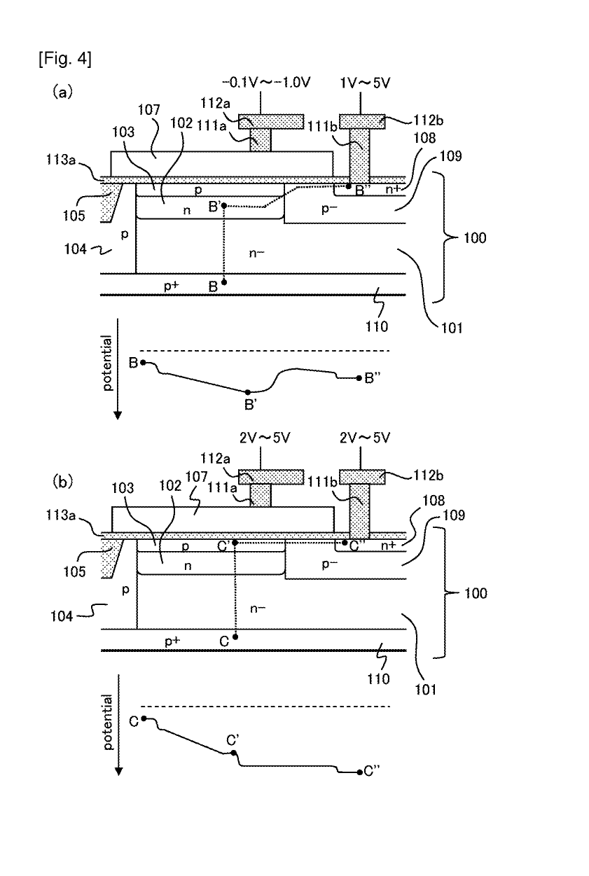

FIG. 4 is a diagram illustrating an operation of such a solid-state imaging apparatus.

For example, in the solid-state imaging apparatus 100a, 0.1 V to 1.0 V of negative voltage is generated and is applied to the transfer gate electrode 107 and 1 V to 5 V of positive voltage is applied to the FD section 108 during the electric charge accumulating period by one of the peripheral circuit sections (i.e., a vertical scanning circuit 153, a horizontal scanning section 152, a signal processing circuit 154, a timing generating section 156, and the like) disposed on the first main surface side of the semiconductor substrate 100 so as to be positioned in the periphery of the pixel section. Further, during the electric charge accumulating period, the electric potential of the first conductivity type front surface semiconductor region 103 in the pixel section is fixed to the grounding electric potential of the peripheral circuit sections except for the pixel section 151, through the first conductivity type well region 104, first conductivity type back surface semiconductor region 110 and the like.

FIG. 4(a) illustrates a potential distribution of a period during which photoelectric conversion is performed and signal charges are accumulated.

Voltage of 1 V to 5 V is applied to the signal charge accumulating section 108 (FD section) and negative electric potential with in the range between 0.1 V and 1.0 V is provided by the grounding electric potential to the transfer gate electrode 107, so that the electric potential of the electric charge accumulating region 102 will be fixed in such a manner that the hole concentration will be stabilized on the front surface thereof, and the generation of noise electric charges will be suppressed. Further, excess electric charges accumulated in the electric charge accumulating region are drained to the second conductivity type signal charge accumulating section (Floating Diffusion section) 108 over the potential gradient in the path illustrated as B-B′-B″ in FIG. 4(a).

Further, during an electric charge transferring period during which signal charges accumulated in the photoelectric conversion element during the electric charge accumulating period are transferred to the second conductivity type signal charge accumulating section (FD section) 108, a positive electric potential difference is provided between the transfer gate electrode 107 and the first conductivity type front surface semiconductor region 103 so that the electric potential of the transfer gate electrode 107 will be greater than that of the first conductivity type front surface semiconductor region 103.

FIG. 4 (b) illustrates a potential distribution of a period during which signal charges are transferred.

Power source voltage within the range between 2 V and 5 V is applied to the transfer gate electrode 107 and the signal charge accumulating section 108, so that the potential of the first conductivity type front surface semiconductor region (front surface p region) 103 and the second conductivity type electric charge accumulating region 102 will be modulated, and signal charges gathered in the second conductivity type electric charge accumulating region 102 will be read out to the FD section 108, following the potential gradient in the path illustrated as C-C′-C″ in FIG. 4(b).

As such, by applying an electric potential during the electric charge accumulating period between the transfer gate electrode 107 and the first conductivity type front surface semiconductor region 103 so that the electric potential of the transfer gate electrode 107 will be smaller relative to that of the first conductivity type front surface semiconductor region 103, a stable hole concentration can be secured in the first conductivity type front surface semiconductor region 103, thereby shortening the life span of thermally generated carriers (electrons) and reducing noise electric charges.

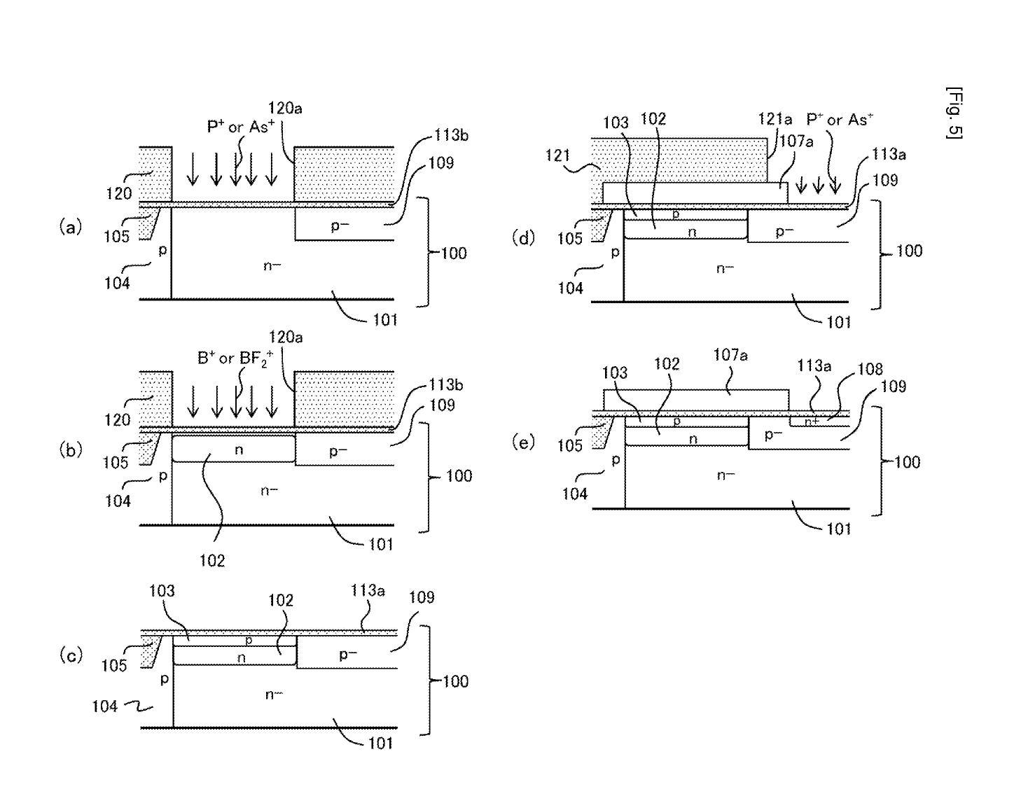

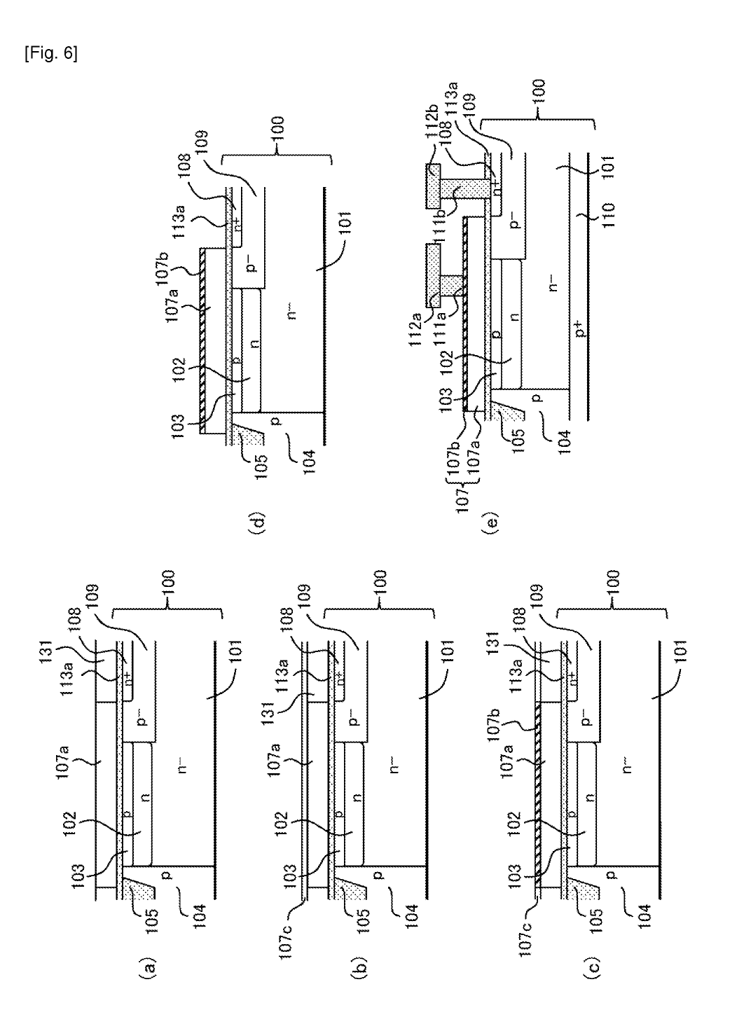

Next, a method for manufacturing a solid-state imaging apparatus according to Embodiment 1 of the present invention will be described hereinafter with reference to FIGS. 5 and 6.

FIGS. 5 and 6 are each a diagram for describing a method for manufacturing a solid-state imaging apparatus according to Embodiment 1 of the present invention. FIGS. 5(a) to 5(e) illustrate cross sectional views for describing steps of forming a photoelectric conversion element and steps of forming a polysilicon layer constituting a transfer gate electrode. FIGS. 6(a) to 6(e) illustrate cross sectional views for describing steps of forming a reflection film constituting a transfer gate electrode.

First, an element separating region 105 is formed on a first conductivity type semiconductor substrate (e.g., p type silicon substrate) 100. The element separating region 105 is formed by forming a trench in the front surface of the p-type silicon substrate 100 and filling the trench with an insulating material such as an oxide. In FIG. 2(a), the thick solid line indicates the border of the element separating region.

Thereafter, a p-well region 104 is formed in the first conductivity type semiconductor substrate 100, and an n⁻ type semiconductor region 101 is formed in the p-well region 104 as a second conductivity type photoelectric conversion region of a photoelectric conversion element. Further, an electric charge transfer section p⁻ region 109 is formed in the front surface region of the n⁻ type semiconductor region 101.

Next, an ion implantation protective film 113b is formed, and thereafter, n-type impurities, such as phosphor (p⁺) or arsenic (As⁺), are selectively implanted using a resist mask 120 with an opening 120a as illustrated in FIG. 5(a). As a result, a second conductivity type electric charge accumulating region 102 is formed so as to constitute a photodiode that functions as a photoelectric conversion element (FIG. 5(b)).

Subsequently, as illustrated in FIG. 5(b), p-type impurities, such as boron (B⁺) or BF2⁺, are selectively implanted using the same resist mask 120 to form a front surface p-region 103 as a first conductivity type front surface semiconductor region.

Next, as illustrated in FIG. 5(c), after the resist mask 120 is removed, a semiconductor region, constituting a semiconductor element in the peripheral circuit section, is formed within the semiconductor substrate. Thereafter, the ion implantation protective film 113b is removed and a gate insulation film (gate oxide film) 113a is formed on the front surface. Further, an electrode material such as polysilicon is deposited by a vapor phase growth method, and this electrode material is anisotropically etched by a technique of dry etching, such as plasma etching, to form a polysilicon gate layer 107a (FIG. 5(d)).

At this stage, as illustrated in FIG. 5(d), the polysilicon gate layer 107a is disposed over entirely the surfaces on front surface side of the semiconductor substrate, of the front surface p-region 103, the electric charge transfer section p⁻ region 109, and the p-well region 104 that surrounds these regions.

Subsequently, n-type impurities, such as phosphor (p⁺) or arsenic (As⁺), are implanted into the opening of the polysilicon gate layer 107a, using a resist mask 121 with an opening 121a, to form a second conductivity type signal charge accumulating section (FD section) 108, which will be an electric charge reading out region (FIG. 5(e)).

Subsequently, an insulation film (e.g., a silicon oxide film) 131 is formed on the entire surface, and then etchback is performed on the insulation film so that the surface of the polysilicon gate layer 107a will be exposed (FIG. 6(a)).

Thereafter, a high melting point metal layer 107c is formed by depositing a high melting point metal material such as tungsten (FIG. 6(b)), and the high melting point metal layer 107c is silicidized by thermal treatment to form a high melting point metal silicide layer 107b (FIG. 6(a)).

Thereafter, the high melting point metal layer 107c and the silicon oxide film 131 therebelow are selectively removed to form a transfer gate electrode 107 (FIG. 6(d)).

Next, after an interlayer insulation film (not shown) is formed, contact sections 111a and 111b are formed, and wiring layers 112a and 112b are also formed. Thereafter, through a supporting substrate laminating step of laminating the p-type silicon substrate 100 on a supporting substrate and a silicon substrate thinning step of thinning the p-type silicon substrate 100 by polishing the back surface side of the p-type silicon substrate 100, when the back surface side of the n⁻ type semiconductor region 101 is exposed, a back surface p⁺ region 110 is formed by an impurity implanting and thermal treatment step of implanting impurities into the back surface of the n⁻ type semiconductor region 101 and performing thermal treatment thereon (FIG. 6(e)).

Note that the transfer gate having a two layer structure described above may also be formed by forming a polysilicon layer and further forming a metal silicide layer and then patterning the two layers by dry etching processing, such as plasma etching.

Next, the working effect of the solid-state imaging apparatus according to the present invention will be described hereinafter.

First, between the solid-state imaging apparatus 100a according to Embodiment 1 of the present invention and the conventional solid-state imaging apparatus 1, the disposition of the transfer gate electrodes are different, as can be seen from the comparison between FIGS. 2, 3 and 10.

Specifically, the transfer gate electrode 32 is formed only in a region (i.e., a channel region for the transfer gate 32) between the n-type electric charge accumulating region 24 and the signal charge electric accumulating section (electric charge n⁺ region) 25 in the conventional solid-state imaging apparatus 1 (see FIG. 13), and the transfer gate electrode 32 is not disposed over the n-type electric charge accumulating region 24 that constitutes the photoelectric conversion element (i.e., a photodiode). Furthermore, the transfer gate electrode 32 has a single layered structure of a polysilicon film in the conventional solid-state imaging apparatus 1.

On the other hand, in the solid-state imaging apparatus 100a according to Embodiment 1 of the present invention, the transfer gate electrode 107 is formed in such a manner to be disposed over entirely, not only the surface on the front surface side of the substrate of the first conductivity type electric charge transferring region (electric charge transfer section p⁻ region) 109 of each pixel, but also the surface on the front surface side of the substrate of the second conductivity type electric charge accumulating region (n type semiconductor region) 102 (FIG. 3). Further, in the solid-state imaging apparatus 100a according to Embodiment 1 of the present invention, the transfer gate electrode 107 has a two-layer structure of a polysilicon layer 107a and a high melting point metal silicide layer 107b formed as a reflection film to cover the surface of the polysilicon layer 107a.

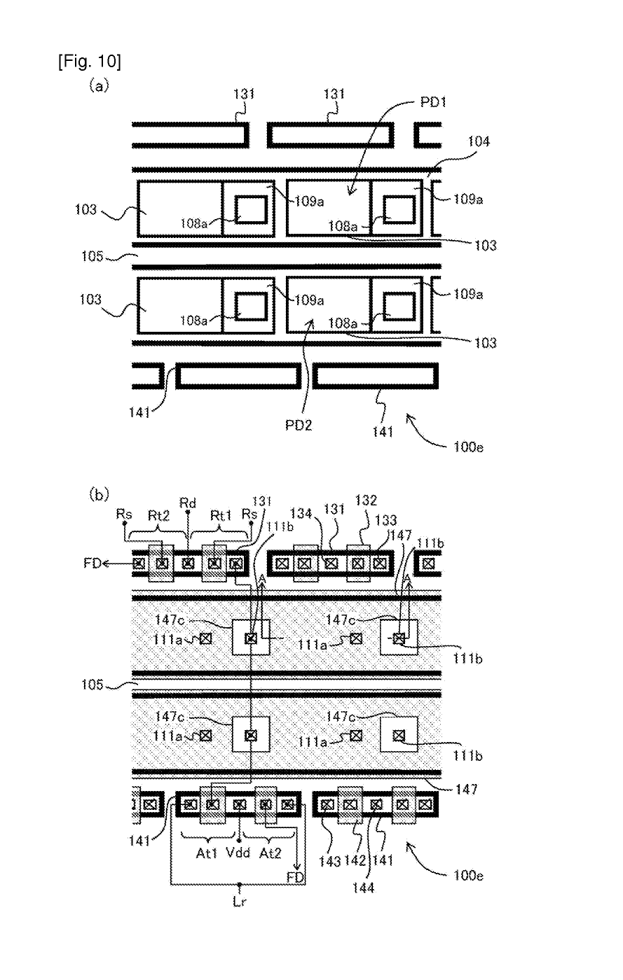

Furthermore, the solid-state imaging apparatus 100a according to the present invention is different from the comparative conventional solid-state imaging apparatus 1, in the impurity concentrations of the first conductivity type front surface semiconductor region (front surface p region) 103 formed on the front surface side of the second conductivity type electric charge accumulating region (n type semiconductor region) 102, as seen from the comparison between FIG. 3 and FIG. 10. Specifically, in the solid-state imaging apparatus 100a according to Embodiment 1 of the present invention, the impurity concentration of the first conductivity type front surface semiconductor region (front surface p region) 103 formed on the front surface side of the second conductivity type electric charge accumulating region (n type semiconductor region) 102 is smaller than the impurity concentration of the front surface semiconductor region (front surface P⁺ region) 23 in the conventional solid-state imaging apparatus 1.

In the solid-state imaging apparatus 100a according to Embodiment 1, the transfer gate electrode 107 is disposed over the surface on the first main surface side of the second conductivity type electric charge accumulating region 102, so that the second conductivity type electric charge accumulating region 102 of the photoelectric conversion element will not receive any damage from plasma etching in the process of forming the transfer gate electrode, thus suppressing the generation of noise electric charges due to crystal defects.

Thus, defects such as white spots can be suppressed even in reducing the impurity concentration of the first conductivity type front surface semiconductor region 103, which is formed on the front surface region of the second conductivity type electric charge accumulating region 102. This will also allow the impurity concentration of the first conductivity type electric charge transferring region 109 adjacent to the second conductivity type electric charge accumulating region 102 to be suppressed low. As a result, it is possible to increase the amount of the variation in the potential level in this first conductivity type electric charge transferring region 109, thereby enhancing the efficiency of transferring electric charges.

Further, since the transfer gate electrode 107 is disposed over entirely the surfaces, on the front surface side of the semiconductor substrate, of the second conductivity type electric charge accumulating region 102 of the photoelectric conversion element, the first conductivity type electric charge transferring region 109, and the p-well region 104 surrounding the second conductivity type signal charge accumulating section 108, these regions will not receive any damage due to plasma etching in the process of forming the transfer gate electrode, and as a result, the crystallinity of these semiconductor regions can be favorable.

Further, since the transfer gate electrode 107 is comprised of the polysilicon gate layer 107a and the high melting point metal silicide layer 107b formed to cover the surface of the polysilicon gate layer 107a, light entering from the back surface side of the semiconductor substrate 100 and transmitting through the semiconductor substrate 100 and the polysilicon layer 107a of the transfer gate electrode 107 will be reflected by the high melting point metal silicide layer 107b of the transfer gate electrode 107 and will return inside the semiconductor substrate again. This reflection will make the efficient use of incident light possible. Further, since the transfer gate electrode 107 is disposed over the surfaces, on the front substrate surface side of the semiconductor substrate, of the electric charge transfer section p⁻ region 109 and the front surface p-region 103, it becomes possible to avoid the problem of incident light coming from the back surface side of the substrate that escapes through the gap between the transfer gate electrode 32 and the reflection layer 43 as in the conventional solid-state imaging apparatus described with reference to FIG. 13.

Further, the resistance of the transfer gate electrode 107 is reduced by the high melting point metal silicide layer 107b formed on the surface of the polysilicon gate layer 107a, thereby reducing its power consumption of the solid-state imaging apparatus.

Further, since all of the impurity regions within the semiconductor substrate, other than the FD section (electric charge accumulating n⁺ region) 108, are formed prior to the formation of the transfer gate electrode, the impurity regions within the semiconductor substrate, other than the FD section 108, are formed in the state where the impurity regions have not been damaged by plasma etching at the forming of the transfer gate electrode. This will enable securing favorable crystallinity, and eliminate causes of deteriorating the characteristics, such as leak current.

As such, such plasma damage due to etching of gate electrodes can be prevented from influencing the surface of the photoelectric conversion element, and thus, it will not be necessary to form a p⁺ region on the surface of the photoelectric conversion element.

As a result, it becomes possible to eliminate implantation damage associated with the forming of such a p⁺ region, and it becomes possible to eliminate a surface p⁺ region of the photoelectric conversion element as well as a transition region from the front p⁺ region to the electric conversion transfer section p⁻ region, on the front surface side of the semiconductor substrate 100. Specifically, the elimination of such a transition region from the front p⁺ region to the electric conversion transfer section p⁻ region of the photoelectric conversion element facilitates the securing of transfer characteristics. Further, disposing the transfer gate electrode over the surface of the photoelectric conversion element allows for the increase in the hole concentration during accumulation of electric charges. More specifically, the application of negative bias to the transfer gate electrode during accumulation of electric charges allows for the increase in the hole concentration in the front surface p-region of the photoelectric conversion element.

As a result, not only the generation of noise electric charges is suppressed on the surface of the photoelectric conversion element, but also the life span of generated noise electric charges can be shortened. The suppression of noise due to noise electric charges can be consistent with the securing of the saturation electric charge amount in the photoelectric conversion element.

### Embodiment 2

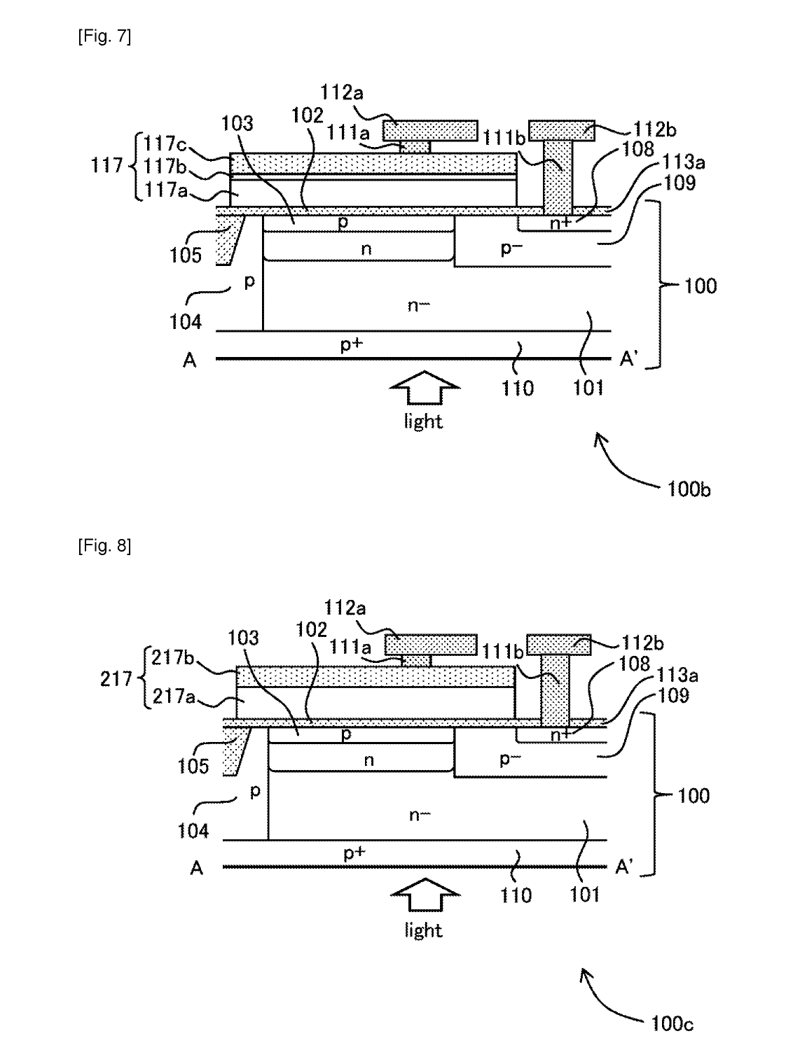

FIG. 7 is a diagram for describing a solid-state imaging apparatus according to Embodiment 2 of the present invention, where it illustrates a portion corresponding to the cross sectional view along the line A-A′ in FIG. 2(b).

A solid-state imaging apparatus 100b according to Embodiment 2 comprises a transfer gate electrode 117, instead of the transfer gate electrode 107 in the solid-state imaging apparatus 100a according to Embodiment 1 described above, where the transfer gate electrode 117 has a cross sectional structure which is different from the transfer gate electrode 107. The rest of the structure is identical to the solid-state imaging apparatus 100a according to Embodiment 1.

Specifically, in the solid-state imaging apparatus 100b according to Embodiment 2, the transfer gate electrode 117 has a multi-layered structure comprising: a polysilicon gate layer 117a formed on a gate insulation film 102; a high melting point metal silicide layer 117b; and a metal layer 117c formed on the surface of the high melting point metal silicide layer 117b. Here, tungsten, cobalt, titanium, molybdenum, hafnium, platinum or nickel is used for the high melting point metal material constituting the high melting point metal silicide layer. Tungsten, cobalt, titanium, molybdenum, hafnium, platinum or nickel is also used for the metal material constituting the metal layer of the transfer gate electrode.

Note that, in Embodiment 2 as well, after a polysilicon layer and a high melting point metal silicide layer are formed similarly to the method in Embodiment 1, the transfer gate electrode 117 may be formed by selectively forming a metal layer on this high melting point metal. Alternatively, the transfer gate electrode 117 with a three-layered structure may be formed by the method where after a polysilicon layer is formed, a metal silicide layer and a metal layer are further successively formed and then these three layers are patterned by dry etching.

In the solid-state imaging apparatus 100b with such a configuration, the transfer gate electrode 117 has the three-layered structure with the polysilicon gate layer 117a, the high melting point metal silicide layer 117b thereon, and the metal layer 117c thereon. Thus, the resistance of the transfer gate electrode 117 can be further reduced, and light coming from inside the semiconductor substrate 100 towards the outside can be reflected back at high reflectivity and returned into the semiconductor substrate 100.

### Embodiment 3

FIG. 8 is a diagram for describing a solid-state imaging apparatus according to Embodiment 3 of the present invention, where it illustrates a cross sectional view along the line A-A′ in FIG. 2(b).

A solid-state imaging apparatus 100c according to Embodiment 3 comprises a transfer gate electrode 217, instead of the transfer gate electrode 107 in the solid-state imaging apparatus 100a according to Embodiment 1 described above, where the transfer gate electrode 217 has a cross sectional structure which is different from the transfer gate electrode 107. The rest of the structure is identical to the solid-state imaging apparatus 100a according to Embodiment 1.

Specifically, in the solid-state imaging apparatus 100a according to Embodiment 3, the transfer gate electrode 217 has a multi-layered structure comprising: a polysilicon gate layer 217a formed on a gate insulation film 102; and a metal layer 217b formed on the surface thereof. Here, tungsten, cobalt, titanium, molybdenum, hafnium, platinum or nickel is used for the metal material constituting the metal layer 217b of the transfer gate electrode 217.

Note that in Embodiment 3 as well, after a polysilicon gate layer is patterned similarly to the method in Embodiment 1, the transfer gate electrode 217 may be formed by selectively forming a metal layer on this polysilicon gate layer. Alternatively, the transfer gate electrode with a two-layered structure in Embodiment 3 may be formed in the method where after a polysilicon gate layer is formed, a metal layer is further successively formed and then these two layers are patterned by dry etching.

In the solid-state imaging apparatus 100c with such a configuration, the transfer gate electrode 217 has a two-layered structure with the polysilicon gate layer 217a and the metal layer 117c thereon. Thus, the resistance of the transfer gate electrode 217 can be further reduced by such a relatively simple structure, and light coming from inside the semiconductor substrate 100 towards the outside can be reflected back at high reflectivity and returned into the semiconductor substrate.

### Embodiment 4

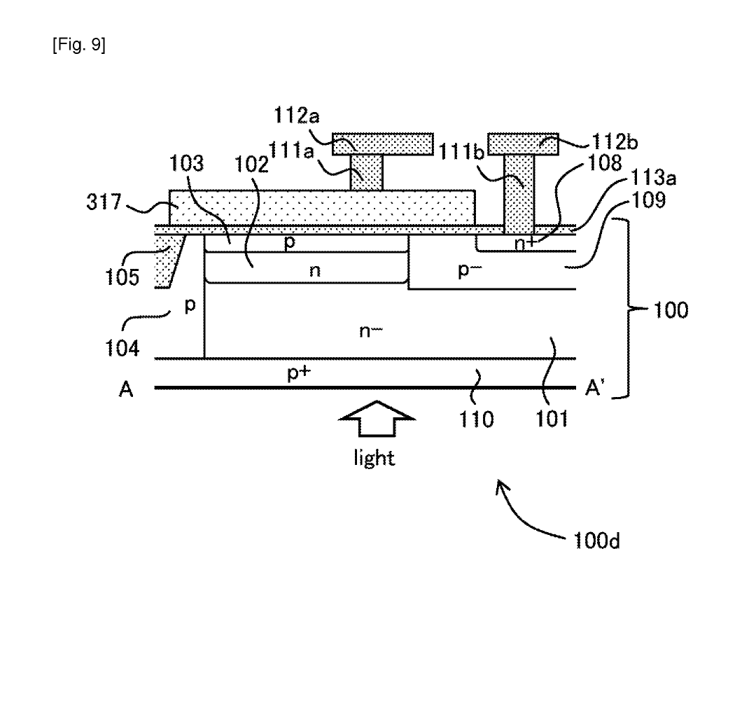

FIG. 9 is a diagram for describing a solid-state imaging apparatus according to Embodiment 4 of the present invention, where it illustrates a portion corresponding to the cross sectional view along the line A-A′ in FIG. 2(b).

A solid-state imaging apparatus 100d according to Embodiment 4 comprises a transfer gate electrode 317, instead of the transfer gate electrode 107 in the solid-state imaging apparatus 100a according to Embodiment 1 described above, where the transfer gate electrode 317 has a cross sectional structure which is different from the transfer gate electrode 107. The rest of the structure is identical to the solid-state imaging apparatus 100 according to Embodiment 1.

Specifically, in the solid-state imaging apparatus 100d according to Embodiment 4, the transfer gate electrode 317 has a single-layered structure with a metal layer. Here, tungsten, cobalt, titanium, molybdenum, hafnium, platinum or nickel is used for the metal material constituting the transfer gate electrode 317.

Note that in Embodiment 4 as well, the transfer gate electrode 317 may be formed by patterning the formed metal layer by dry etching.

In the solid-state imaging apparatus 100d with such a configuration, the transfer gate electrode 317 has a single-layered structure with the metal layer. Thus, the resistance of the transfer gate electrode 317 can be further reduced by such a relatively simple structure, and light coming from inside the semiconductor substrate 100 towards the outside can be reflected back at high reflectivity and returned into the semiconductor substrate.

Note that the metal layer 317 may be a multi-layered structure made of the metal material described above. Also, in such a case, the reduction of the resistance can be achieved, and light entered from the back surface of the semiconductor substrate can be reflected back at high reflectivity on the front surface side of the semiconductor substrate and returned into the semiconductor substrate.

### Embodiment 5

FIG. 10 is a plane view for describing a solid-state imaging apparatus according to Embodiment 5 of the present invention, where FIG. 10(a) illustrates a disposition of an impurity implantation region relative to an element separating region and FIG. 10(b) illustrates a disposition of a contact section and a transfer gate electrode relative to an element separating region.

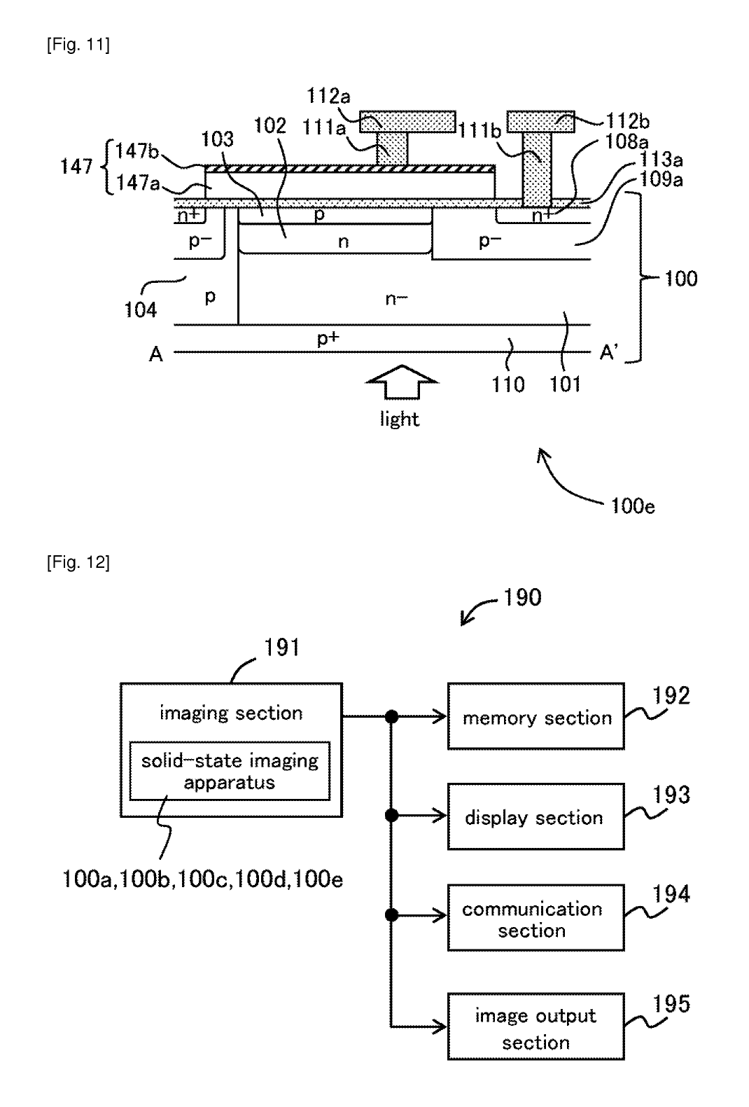

FIG. 11 illustrates a cross sectional view along the line A-A′ in FIG. 10(b).

A solid-state imaging apparatus 100e according to Embodiment 5 is obtained by varying the disposition with regard to the first conductivity type electric charge transferring region (electric charge transfer section p⁻ region) 109 and the second conductivity type signal charge accumulating section (electric charge n⁺ region) 108 in the solid-state imaging apparatus 100a according to Embodiment 1.

Specifically, in the solid-state imaging apparatus 100e according to Embodiment 5, a second conductivity type signal charge accumulating section (electric charge n⁺ region) 108a is disposed in between adjacent second conductivity type electric charge accumulating regions (n-type semiconductor regions) 102 arranged in the row direction, and a first conductivity type electric charge transferring region (electric charge transfer section p⁻ region) 109a is disposed in between this second conductivity type signal charge accumulating section 108a and a corresponding second conductivity type electric charge accumulating region 102. Further, the first conductivity type electric charge transferring region 109a is disposed in such a manner to surround the second conductivity type signal charge accumulating section 108a.

The rest of the configuration is identical to that of the solid-state imaging apparatus according to Embodiment 1.

Note that, also in the solid-state imaging apparatus 100e according to Embodiment 5, two reset transistors Rt1 and Rt2 are formed above a belt-shaped diffusion region 131, and two reset gate electrodes 132 to which a reset signal Rs is applied are disposed in such a manner to intersect with the belt-shaped diffusion region 131, with a gate insulation film (not shown) interposed therebetween. A drain signal Rd is applied through a contact section 134 to a common drain region between the two reset gate electrodes 132 in the belt-shaped diffusion region 131. Further, the source region of one of the reset transistors, i.e., reset transistor Rt1, is connected with wiring 112b that is connected with the signal charge accumulating section (FD section) 108, with a contact section 133 interposed therebetween. The source region of the other reset transistor, i.e., reset transistor Rt2, is connected with a second conductivity type signal charge accumulating section (FD section) common to the pixel in the first row and the pixel in the second row in the pixel section 151 illustrated in FIG. 1.

Two amplifying transistors At1 and At2 are formed on the belt-shaped diffusion region 141, and an amplifying gate electrode 142 is disposed in such a manner to intersect with the belt-shaped diffusion region 141, with a gate insulation film (not shown) interposed therebetween. A power source voltage Vdd (e.g., 2.5V) is applied through a contact section 144 to a common drain region between the two amplifying gate electrodes 142 in the belt-shaped diffusion region 141. Further, the source region of one of the amplifying transistors, i.e., amplifying transistor At1, is connected with a reading signal line Lr with a contact section 143 interposed therebetween. The source region of the other amplifying transistor, i.e., amplifying transistor At2, is also connected with the reading signal line Lr corresponding to the same pixel column, with the contact section 143 interposed therebetween. Further, the gate electrode 142 of one of the amplifying transistors, i.e., amplifying transistor At1, is connected with wiring 112b that is connected with the signal charge accumulating section (FD section) 108. The gate electrode 142 of the other amplifying transistor, i.e., amplifying transistor At2, is connected with a signal charge accumulating section (FD section) common to the pixel in the fifth row and the pixel in the sixth row of the pixel section 151 illustrated in FIG. 1.

Next, the working effect of the solid-state imaging apparatus according to Embodiment 5 will be described hereinafter.

In the solid-state imaging apparatus 100e having such a configuration as described above, the second conductivity type signal charge accumulating section (electric charge n⁺ region) 108a is disposedwithinan opening 147c of a transfer gate electrode 147 of a two-layered structure with a polysilicon layer 147a and a high melting point metal silicide layer 147b formed to cover the surface of the polysilicon layer 147a, similarly to Embodiment 1, and the second conductivity type signal charge accumulating section (electric charge n⁺ region) 108a does not come in contact with an element separating region 105. Accordingly, transfer gate electrodes 147, which are disposed in parallel (transfer gate electrodes disposed adjacent to each other top and bottom in FIG. 10(b)), can be disposed even closer to each other, which makes it possible to reduce a pixel area.

In the disposition of the pixel section illustrated in FIG. 10(a), it becomes possible to dispose the second conductivity type signal charge accumulating section (FD section) 108a away from the p-well region 104 accompanying the element separating region 105. This will facilitate reducing the impurity concentration in the electric charge transfer section p⁻ region 109a.

Specifically, since the p-well regions 104 are disposed on both the left and right sides of the second conductivity type signal charge accumulating section 108 in the solid-state imaging apparatus 100a according to Embodiment 1, width of the first conductivity type electric charge transferring region 109 is restricted by the width of the second conductivity type signal charge accumulating section 108. On the other hand, since the second conductivity type signal charge accumulating section 108 is disposed away from the p-well region 104 in the solid-state imaging apparatus 100e according to Embodiment 5, the electric charge transfer section p⁻ region 109a, including a transferring path from the second conductivity type electric charge accumulating region 102 of the photoelectric conversion element to the second conductivity type signal charge accumulating section 108a, can be disposed in such a manner to surround the second conductivity type signal charge accumulating section 108a.

Thus, it is possible to increase the area of the electric charge transfer section p⁻ region 109a, and to suppress the increase in the impurity concentration of the electric charge transfer section p⁻ region 109a, which is due to impurity diffusion from the p-well region 104 positioned in the periphery of the electric charge transfer section p⁻ region 109a. Thus, it becomes possible to make further improvement on transferring characteristics can be made.

Further, since the transfer gate electrode 147 is comprised of the polysilicon gate layer 147a and the high melting point metal silicide layer 147b formed to cover the surface of the polysilicon gate layer 147a, light entering from the back surface side of the semiconductor substrate 100 and being transmitted through the semiconductor substrate 100 and the polysilicon layer 147a will be reflected by the high melting point metal silicide layer 147b of the transfer gate electrode 147 and will return inside the semiconductor substrate again. This reflection will make the efficient use of incident light possible. Further, since the transfer gate electrode 147 is disposed over entirely the surfaces, on the front surface side of the semiconductor substrate, of the electric charge transfer section p⁻ region 109a and the front surface p-region 103, it becomes possible to prevent the problem of incident light coming from the back surface side of the substrate from escaping through the gap between the transfer gate electrode 32 and the reflection layer 43 as in the conventional solid-state imaging apparatus described with reference to FIG. 13.

Further, the resistance of the transfer gate electrode 147 is reduced by the high melting point metal silicide layer 147b formed on the surface of the polysilicon gate layer 147a, making it possible to reduce its power consumption of the solid-state imaging apparatus.

Further, the transfer gate electrodes 147 that are disposed in parallel can be disposed to be even closer to each other, making it possible to reduce the area for pixels.

According to Embodiments 1 to 5 described above, the transfer transistor is indicated as such a transistor in which a reflection film forms at least one layer that constitutes a gate electrode located in such a manner to extend from the region occupied by the transfer transistor on the first main surface of the semiconductor substrate to the region occupied by the photoelectric conversion element on the first main surface, and is disposed over the region. However, the present invention is not limited to these embodiments, and a reflection film may form at least a part of at least one layer constituting the gate electrode of the transfer transistor. Any publicly known methods (e.g., a method for depositing a material that constitutes a reflection film and selectively etching the deposited layer) can be used as the method for “partially” forming a reflection film in a specific layer as described above.

In addition, the reflection film may also be that formed on a gate electrode of the transfer transistor. In such a case, the reflection film formed on a gate electrode of the transfer transistor is one which is different from the gate electrode of the transfer transistor, and the reflection film does not necessarily function as a gate electrode of the transfer transistor. For example, the reflection film formed on the gate electrode of the transfer transistor may be an insulated reflection film having no conductivity. Alternatively, while the reflection film formed on the gate electrode of the transfer transistor may be a reflection film having conductivity (e.g., a high melting point silicide layer or a metal layer), it is necessary in this case for the conductive reflection film to be insulated from the gate electrode. Further, a method for forming a gate electrode and then forming an insulated reflection film on the gate electrode, or a method for forming a gate electrode and then forming a conductive reflection film with an insulation film disposed on the gate electrode, can be used as the method for forming a reflection film on such a gate electrode of the transfer gate.

Further, the reflection film formed on the gate electrode of the transfer transistor is not limited to those formed on the entire surface of the gate electrode. The reflection film may be those formed on at least apart of the gate electrode. Any publicly known methods (e.g., a method for depositing a material that constitutes a reflection film and selectively etching the deposited layer) can be used as the method for “partially” forming a reflection film on the gate electrode as described above.

Further, although not specifically described in Embodiments 1 to 5 described above, an electronic information device will be described hereinafter. The electronic information device having an image input device, such as a digital camera (e.g., digital video camera or digital still camera), an image input camera, a scanner, a facsimile machine and a camera-equipped cell phone device, includes an imaging section using at least one of the solid-state imaging apparatuses 100 to 100e according to Embodiments 1 to 5 described above as an image input device.

### Embodiment 6

FIG. 12 is a block diagram schematically illustrating an exemplary configuration of an electronic information device, as Embodiment 6 of the present invention, using the solid-state imaging apparatus according to any of Embodiments 1 to 5 in an imaging section.

An electronic information device 190 according to Embodiment 6 of the present invention as illustrated in FIG. 12 comprises at least one of the solid-state imaging apparatuses 100a, 100b, 100c, 100d and 100e according to Embodiments 1 to 5 of the present invention as an imaging section 191 for capturing a subject. The electronic information device 190 further comprises at least any of: a memory section 192 (e.g., recording media) for data-recording a high-quality image data obtained by image capturing using the imaging section, after predetermined signal processing is performed on the image data for recording; a display section 193 (e.g., liquid crystal display device) for displaying this image data on a display screen (e.g., liquid crystal display screen) after predetermined signal processing is performed for display; a communication section 194 (e.g., transmitting and receiving device) for communicating this image data after predetermined signal processing is performed on the image data for communication; and an image output section 195 for printing (typing out) and outputting (printing out) this image data.

As described above, the present invention is exemplified by the use of its preferred embodiments. However, the present invention should not be interpreted solely based on these embodiments described above. It is understood that the scope of the present invention should be interpreted solely based on the claims. It is also understood that those skilled in the art can implement equivalent scope of technology, based on the description of the present invention and common knowledge from the description of the detailed preferred embodiments of the present invention. Furthermore, it is understood that any patent, any patent application and any references cited in the present specification should be incorporated by reference in the present specification in the same manner as the contents are specifically described therein.

### INDUSTRIAL APPLICABILITY

In the field of a solid-state imaging apparatus, a manufacturing method of the solid-state imaging apparatus, and an electronic information device, the present invention can achieve: a solid-state imaging apparatus capable of achieving improved sensitivity by efficiently reflecting light that has entered through the other of the surfaces of a semiconductor substrate, which is opposite from one of the surfaces within which a photoelectric conversion element is formed, by a reflection film formed above one of the surfaces of the semiconductor substrate; a method for manufacturing the solid-state imaging apparatus; and an electronic information device.

### REFERENCE SIGNS LIST

100 first conductivity type semiconductor substrate
100a to 100e solid-state imaging apparatus
101 second conductivity type photoelectric conversion region (n⁻ type semiconductor region)
102 second conductivity type electric charge accumulating region (n⁻ type semiconductor region)
103 first conductivity type front surface semiconductor region (front surface p region)
104 first conductivity type well region (p-well region)
105 element separating region
107, 117, 217, 317 transfer gate electrode
108, 108a second conductivity type signal charge accumulating section (electric charge accumulating n⁺ region)
109, 109a first conductivity type electric charge transferring region (electric charge transfer section p⁻ region)
110 back surface p⁺ region
111a, 111b contact section
112a, 112b wiring layer
113a gate insulation film (gate oxide film)
113b ion implantation protective film
120, 121 resist
120a, 121a resist opening
190 electronic information device
191 imaging section
192 memory section
193 display section
194 communication section
195 image output section

1. A solid-state imaging apparatus comprising a photoelectric conversion element formed in a first conductivity type semiconductor substrate, for photoelectrically converting incident light to generate signal charges, in which the signal charges generated by the photoelectric conversion element are converted into an image signal by signal processing which is outputted,
the solid-state imaging apparatus further comprising a transfer transistor formed on a first main surface of the semiconductor substrate, for transferring the signal charges generated by the photoelectric conversion element to outside the photoelectric conversion element,
wherein the transfer transistor comprises a gate electrode located in such a manner to extend from a region occupied by the transfer transistor on the first main surface to a region occupied by the photoelectric conversion element on the first main surface, and is disposed over the regions, and
wherein at least one layer constituting the gate electrode of the transfer transistor is comprised of a reflection film having a reflection rate greater than that of polysilicon, or a reflection film having a reflection rate greater than that of polysilicon is formed on the gate electrode of the transfer transistor.

2. A solid-state imaging apparatus according to claim 1,
wherein the photoelectric conversion element comprises:
a second conductivity type photoelectric conversion region for photoelectrically converting incident light taken from a second main surface of the semiconductor substrate on an opposite side from the first main surface; and
a second conductivity type electric charge accumulating region for accumulating, on the first main surface side, the signal charges generated by photoelectric conversion in the second conductivity type photoelectric conversion region, and
wherein the gate electrode of the transfer transistor is formed to be disposed over the surface of the first main surface side of the second conductivity type electric charge accumulating region.

3. A solid-state imaging apparatus according to claim 2, wherein the solid-state imaging apparatus further comprises:
a second conductivity type signal charge accumulating section for accumulating the signal charges transferred from the photoelectric conversion element; and
a first conductivity type electric charge transferring region for transferring the signal charges from the second conductivity type electric charge accumulating region to the second conductivity type signal charge accumulating section,
wherein the second conductivity type electric charge accumulating region and the second conductivity type signal charge accumulating section are disposed away from each other with the first conductivity type electric charge transferring region interposed therebetween.

4. A solid-state imaging apparatus according to claim 3, wherein a space between the second conductivity type electric charge accumulating region and the second conductivity type signal charge accumulating section is equal to or greater than a minimum distance that does not substantially cause a short channel effect, and is equal to or smaller than a maximum distance that is permissible by a degree of integration of pixels in the solid-state imaging apparatus.

5. A solid-state imaging apparatus according to claim 3, wherein a space between the second conductivity type electric charge accumulating region and the second conductivity type signal charge accumulating section is within the range of 0.2 μm to 1.0 μm.

6. A solid-state imaging apparatus according to claim 3, wherein the solid-state imaging apparatus further comprises:
a first conductivity type well region formed within the first conductivity type semiconductor substrate; and
a first conductivity type front surface semiconductor region formed on the first main surface side of the second conductivity type electric charge accumulating region, in such a manner to be disposed over the second conductivity type electric charge accumulating region, and
wherein the first conductivity type front surface semiconductor region has impurity concentration that exceeds impurity concentration of the first conductivity type electric charge transferring region and that is equal to or smaller than impurity concentration of the first conductivity type well region.

7. A solid-state imaging apparatus according to claim 6, wherein the first conductivity type well region is formed to surround the second conductivity type electric charge accumulating region, the first conductivity type electric charge transferring region and the second conductivity type signal charge accumulating section.

8. A solid-state imaging apparatus according to claim 6, wherein the gate electrode of the transfer transistor is formed to be disposed over a region occupied by the first conductivity type well region on the first main surface.

9. A solid-state imaging apparatus according to claim 1, wherein the gate electrode of the transfer transistor has a multi-layered structure comprising a polysilicon layer and a high melting point metal silicide layer formed as a reflection film on a surface of the polysilicon layer.

10. (canceled)

11. A solid-state imaging apparatus according to claim 1, wherein the gate electrode of the transfer transistor has a multi-layered structure comprising a polysilicon layer and a metal layer formed as a reflection film on a surface of the polysilicon layer.

12. (canceled)

13. A solid-state imaging apparatus according to claim 1, wherein the gate electrode of the transfer transistor has a multi-layered structure comprising a polysilicon layer, a high melting point metal silicide layer formed on a surface of the polysilicon layer, and a metal layer formed on a surface of the high melting point metal silicide layer, the high melting point metal silicide layer and the metal layer being formed as a reflection film.

14. (canceled)

15. A solid-state imaging apparatus according to claim 1, wherein the gate electrode of the transfer transistor has a single-layered structure consisting of a high melting point metal layer.

16. A method for manufacturing a solid-state imaging apparatus according to claim 1, the method comprising:
a step of forming the photoelectric conversion element within the first conductivity type semiconductor substrate; and
a step of forming the transfer transistor on the first main surface side in the first conductivity type semiconductor substrate,
wherein the step of forming the transfer transistor comprises:
a step of depositing a constituent material of the gate electrode of the transfer transistor on the first main surface; and
a step of forming a gate electrode by selectively etching the deposited constituent material of the gate electrode, so that the gate electrode extends from the region occupied by the transfer transistor on the first main surface to the region occupied by the photoelectric conversion element on the first main surface, and is disposed over the regions, and
wherein the step of forming a gate electrode comprises a step of forming the reflection film as at least one layer constituting the gate electrode, or the method for manufacturing a solid-state imaging apparatus comprises a step of forming the reflection film on the gate electrode of the transfer transistor.

17. A method for manufacturing a solid-state imaging apparatus according to claim 3, the method comprising:
a step of forming the photoelectric conversion element within the first conductivity type semiconductor substrate; and
a step of forming the transfer transistor in the first conductivity type semiconductor substrate on the first main surface side,
wherein the step of forming the transfer transistor comprises:
a step of depositing a constituent material of the gate electrode of the transfer transistor on the first main surface;
a step of forming a gate electrode by selectively etching the deposited constituent material of the gate electrode, so that the gate electrode extends through the region occupied by the transfer transistor on the first main surface to the region occupied by the photoelectric conversion element on the first main surface, and is disposed over the regions; and
a step of forming the second conductivity type signal charge accumulating section by performing ion implantation using the gate electrode of the transfer transistor as a mask.

18. A method for manufacturing a solid-state imaging apparatus according to claim 6, the method comprising:
a step of forming the photoelectric conversion element within the first conductivity type semiconductor substrate; and
a step of forming the transfer transistor on the first main surface side in the first conductivity type semiconductor substrate,
wherein the step of forming the photoelectric conversion element comprises:
a step of forming the second conductivity type electric charge accumulating region within the first conductivity type semiconductor substrate; and
a step of forming the first conductivity type front surface semiconductor region on the first main surface side in the second conductivity type electric charge accumulating region so as to cover the second conductivity type electric charge accumulating region, and
wherein the second conductivity type electric charge accumulating region and the first conductivity type semiconductor substrate are formed by impurity implantation using the same ion implantation mask.

19. A method for manufacturing a solid-state imaging apparatus according to claim 9, the method comprising:
a step of forming the photoelectric conversion element within the first conductivity type semiconductor substrate; and
a step of forming the transfer transistor in the first conductivity type semiconductor substrate on the first main surface side,
wherein the step of forming the transfer transistor comprises:
a step of depositing the polysilicon layer on the first main surface;
a step of forming a polysilicon gate layer by selectively etching the deposited polysilicon layer, so that the polysilicon gate layer extends from a region occupied by the transfer transistor on the first main surface to a region occupied by the photoelectric conversion element on the first main surface, and is disposed over the regions; and
a step of forming a high melting point metal silicide layer on a surface of the polysilicon gate layer.

20. A method for manufacturing a solid-state imaging apparatus according to claim 11, the method comprising:
a step of forming the photoelectric conversion element within the first conductivity type semiconductor substrate; and
a step of forming the transfer transistor in the first conductivity type semiconductor substrate on the first main surface side,
wherein the step of forming the transfer transistor comprises:
a step of depositing the polysilicon layer on the first main surface;
a step of forming a polysilicon gate layer by selectively etching the deposited polysilicon layer, so that the polysilicon gate layer extends from a region occupied by the transfer transistor on the first main surface to a region occupied by the photoelectric conversion element on the first main surface, and is disposed over the regions; and
a step of forming a metal layer on a surface of the polysilicon gate layer.

21. A method for manufacturing a solid-state imaging apparatus according to claim 13, the method comprising:
a step of forming the photoelectric conversion element within the first conductivity type semiconductor substrate; and
a step of forming the transfer transistor in the first conductivity type semiconductor substrate on the first main surface side,
wherein the step of forming the transfer transistor comprises:
a step of depositing the polysilicon layer, the high melting point metal silicide layer and the metal layer successively on the first main surface; and
a step of forming a gate electrode having a multi-layered structure comprising the polysilicon layer, the high melting point metal silicide layer and the metal layer by selectively etching the deposited polysilicon layer, high melting point metal silicide layer and metal layer, so that the gate electrode extends through a region occupied by the transfer transistor on the first main surface to a region occupied by the photoelectric conversion element on the first main surface, and is disposed over the regions.

22. A method for manufacturing a solid-state imaging apparatus according to claim 15, the method comprising:
a step of forming the photoelectric conversion element within the first conductivity type semiconductor substrate; and
a step of forming the transfer transistor in the first conductivity type semiconductor substrate on the first main surface side,
wherein the step of forming the transfer transistor comprises:
a step of forming the high melting point metal layer on the first main surface; and
a step of forming a gate electrode consisting of the high melting point metal layer by selectively etching the formed high melting point metal layer so that the gate electrode extends from a region occupied by the transfer transistor on the first main surface to a region occupied by the photoelectric conversion element on the first main surface, and is disposed over the regions.

23. An electronic information device comprising the solid-state imaging apparatus according to claim 1.
